(19) United States
(12) Patent Application Publication
(10) Pub. No.: US 2025/0391784 A1
(43) Pub. Date: Dec. 25, 2025

(54) SEMICONDUCTOR PACKAGE

(71) Applicant: SAMSUNG ELECTRONICS CO., LTD., Suwon-si (KR)

(72) Inventor: Weizhong ZHOU, Suzhou Industrial Park (CN)

(73) Assignee: SAMSUNG ELECTRONICS CO., LTD., Suwon-si (KR)

(21) Appl. No.: 18/787,293

(22) Filed: Jul. 29, 2024

(30) Foreign Application Priority Data
Jun. 25, 2024 (CN) 202410827823.5

(51) Int. Cl. H01L 23/00; H01L 23/31; H01L 23/498

(52) U.S. Cl. CPC H01L 23/562; H01L 23/49822; H01L 24/16; H01L 23/3107; H01L 23/49816; H01L 2224/10135; H01L 2224/10165; H01L 2224/16157

(57) ABSTRACT

A semiconductor package includes: a substrate comprising a substrate body, a substrate extension part, and a substrate connection terminal, the substrate body having a first surface and a second surface, the substrate extension part being on the first surface of the substrate body, the substrate connection terminal being on the second surface of the substrate body; a semiconductor chip on the first surface of the substrate body, the semiconductor chip comprising a chip body and a chip extension part, the chip extension part being on a side surface of the chip body; and a mold layer encapsulating the semiconductor chip on the first surface of the substrate body, where the substrate extension part and the chip extension part overlap in a first direction, and the substrate extension part and the chip extension part are spaced apart in the first direction.

### CROSS-REFERENCE TO RELATED APPLICATION

This application claims priority to the Chinese Patent Application No. 202410827823.5, filed on Jun. 25, 2024, in the China National Intellectual Property Administration, the disclosure of which is incorporated by reference herein in its entirety.

### BACKGROUND

### 1. Field

The present disclosure relates to the semiconductor packaging technology, and more particularly, to a semiconductor package and a method of manufacturing the same.

### 2. Description of the Related Art

Recently, a flip-chip-based package structure has been proposed for semiconductor packaging. In a flip-chip package structure, a chip may be mounted on a substrate in a flip-chip form. For example, a connection terminal of the chip may face the substrate and be connected to a connector of the substrate, such that the chip and the substrate may be electrically connected to each other. Generally, solder or any other similar material may be used as the connection terminal of the chip, and a trace or any other similar structure, may be used as the connector of the substrate.

Before being connected to the connector of the substrate, a dipping flux of the connection terminal of the chip may contact and wet the connector of the substrate, thereby removing an organic protection layer disposed on a surface of the connector of the substrate so as to allow an electrical connection between the connection terminal of the chip and the connector of the substrate.

However, due to a warpage of the chip, or due to an inconsistency of warpage between the chip and the substrate, a case of the connection terminal of the chip being apart from the connector of the substrate may occur when the chip is mounted on the substrate. In this case, the connection terminal of the chip may not effectively wet the connector of the substrate, and the organic protection layer on the surface of the connector of the substrate may not be completely removed. As a result, a non-wet defect may occur between the connection terminal of the chip and the connector of the substrate, thereby causing an electrical connection defect, such as disconnection or virtual welding, between the connection terminal of the chip and the connector of the substrate.

### SUMMARY

The present disclosure provides a semiconductor package that reduces or prevents a non-wet defect.

The present disclosure also provides a semiconductor package that implements a die-level warpage correction.

The present disclosure provides a method of manufacturing a semiconductor package that reduces or prevents a non-wet defect.

The present disclosure also provides a method of manufacturing a semiconductor package that implements a die-level warpage correction.

According to an aspect of the present disclosure a semiconductor package comprises: a substrate comprising a substrate body, a substrate extension part, and a substrate connection terminal, the substrate body having a first surface and a second surface opposite to the first surface, the substrate extension part being on the first surface of the substrate body, the substrate connection terminal being on the second surface of the substrate body, and the substrate extension part having a first magnetism; a semiconductor chip on the first surface of the substrate body, the semiconductor chip comprising a chip body and a chip extension part, the chip extension part being on a side surface of the chip body, the chip extension part having a second magnetism; and a mold layer encapsulating the semiconductor chip on the first surface of the substrate body, wherein the substrate extension part and the chip extension part overlap in a first direction, and the substrate extension part and the chip extension part are spaced apart in the first direction.

According to an aspect of the present disclosure, a semiconductor device comprises: a semiconductor package comprising: a substrate comprising a substrate body, a substrate extension part, and a substrate connection terminal, the substrate body having a first surface and a second surface opposite to the first surface, the substrate extension part being on the first surface of the substrate body, the substrate connection terminal being on the second surface of the substrate body, and the substrate extension part having a first magnetism; a semiconductor chip on the first surface of the substrate body, the semiconductor chip comprising a chip body and a chip extension part, the chip extension part being on a side surface of the chip body, the chip extension part having a second magnetism; and a mold layer encapsulating the semiconductor chip on the first surface of the substrate body, wherein the substrate extension part and the chip extension part overlap in a first direction, and the substrate extension part and the chip extension part are spaced apart in the first direction.

### BRIEF DESCRIPTION OF DRAWINGS

The above and other aspects and features will become more apparent from the following descriptions of example embodiments, taken in conjunction with the accompanying drawings, in which:

FIG. 1A is a schematic cross-sectional view illustrating a semiconductor package according to some embodiments;

FIG. 1B schematically illustrates a top view of a substrate of FIG. 1A according to some embodiments;

FIG. 1C schematically illustrates a bottom view of a semiconductor chip of FIG. 1A according to some embodiments;

FIGS. 2A through 2D are schematic diagrams illustrating intermediate steps of a method of manufacturing a semiconductor package according to some embodiments;

FIGS. 3A through 3J are schematic diagrams illustrating intermediate steps of a method of manufacturing a semiconductor package according to some embodiments;

FIGS. 4A through 4E are schematic diagrams illustrating intermediate steps of a method of manufacturing a semiconductor chip according to some embodiments;

FIG. 5 is a schematic cross-sectional view illustrating a step of mounting a semiconductor chip to a substrate according to some embodiments;

FIG. 6 is a schematic cross-sectional view illustrating a step of mounting a semiconductor chip to a substrate according to some embodiments;

FIGS. 7A and 7B schematically illustrate a bottom view of a semiconductor chip and a top view of a substrate according to some embodiments; and

FIGS. 8A and 8B schematically illustrate a bottom view of a semiconductor chip and a top view of a substrate according to some embodiments.

### DETAILED DESCRIPTION

Example embodiments will be described more fully with reference to the accompanying drawings, in which the example embodiments are illustrated. The embodiments described herein are provided as examples, and accordingly, the present disclosure is not limited thereto, and may be implemented in various forms. Each embodiment provided in the following descriptions does not exclude the association with another example or another embodiment that is also provided herein or not provided herein but consistent with the present disclosure. In the drawings, for the sake of clarity, various elements, components, layers, regions, etc., may not be drawn to scale. In the drawings, the same or similar reference numerals denote the same or similar components.

It will be understood that, although terms of “first,” “second,” “third,” etc., may be used herein to describe various elements, components, regions, layers, and/or sections, these elements, components, regions, layers, and/or sections should not be limited by these terms. These terms are used to distinguish one element, component, region, layer, or section from another element, component, region, layer, or section. For example, a first element, component, region, layer, or section described herein may be termed as a second element, component, region, layer, or section without departing from the scope of the present disclosure.

It will be understood that, when an element or layer is referred to as being “on,” “connected to,” or “coupled to” another element or layer, the element or layer may be directly on, directly connected to, or directly coupled to the other element or layer, or an intervening element or layer may also be present. In contrast, when an element is referred to as being “directly on,” “directly connected to,” or “directly coupled to” another element or layer, there is no intervening element or layer.

The specification uses a term of degree including “substantially.” In one or more examples, when specifying that a parameter X may be substantially the same as parameter Y, the term “substantially” may be understood as X being within 10% of Y.

Hereinafter, a semiconductor package and a method of manufacturing the same according to some embodiments of the present disclosure will be described in detail with reference to the accompanying drawings. The semiconductor package of the present disclosure may be incorporated into a semiconductor device such as an electronic device (e.g., handheld device, computer, tablet, etc.).

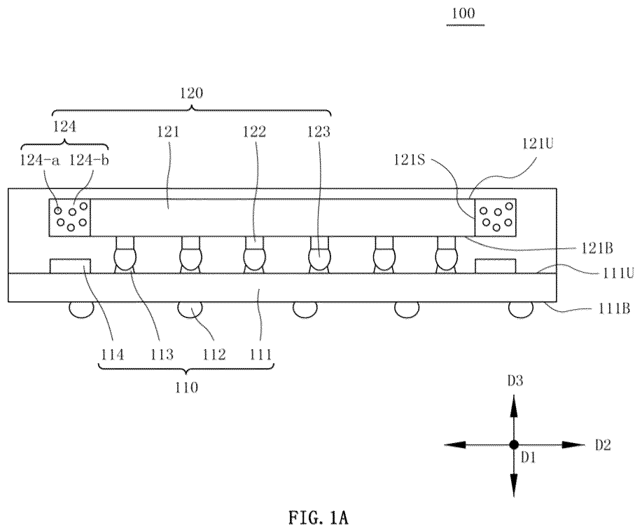

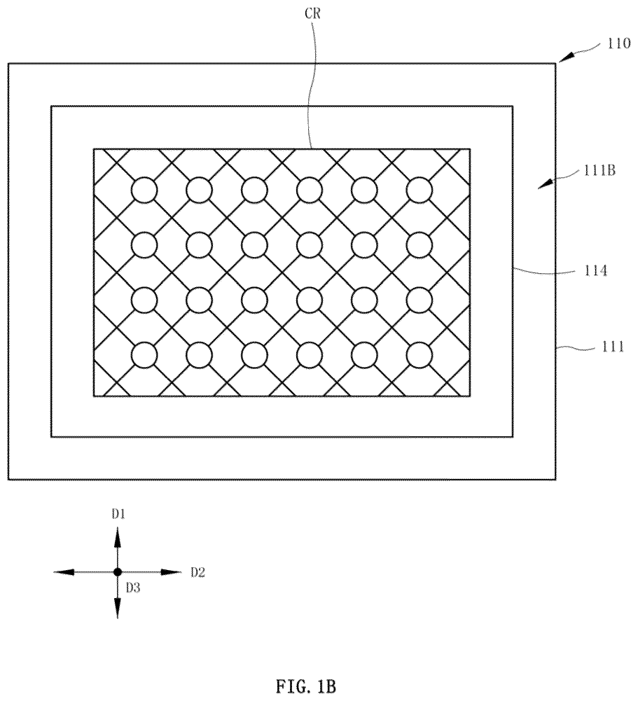

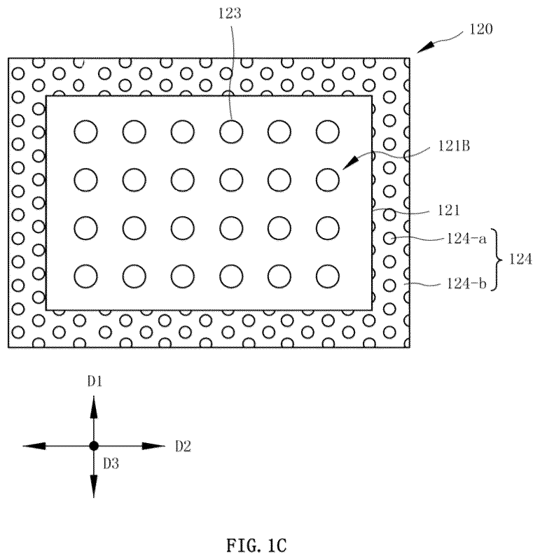

FIG. 1A is a schematic cross-sectional view illustrating a semiconductor package according to some embodiments. FIG. 1B schematically illustrates a top view of the substrate of FIG. 1A. FIG. 1C schematically illustrates a bottom view of the semiconductor chip of FIG. 1A.

Referring to FIG. 1, a semiconductor package 100 according to some embodiments may include a substrate 110 and a semiconductor chip 120 on the substrate 110.

The substrate 110 may include a substrate body 111, a substrate connection terminal 112 below the substrate body 111, and a substrate connector 113 on the substrate body 111. In one or more embodiments, the substrate body 111 may include an insulating substrate or a non-insulating substrate. The insulating substrate may be, for example, a glass substrate, a substrate based on an organic material, or a substrate based on any other suitable material known to one of ordinary skill in the art. The non-insulating substrate may be, for example, a metal substrate, or a substrate based on any other suitable material known to one of ordinary skill in the art.

The substrate body 111 may have a first surface 111U and a second surface 111B opposite to each other. In one or more examples, the first surface 111U of the substrate body 111 may be an upper surface or a top surface of the substrate body 111, and the second surface 111B of the substrate body 111 may be a lower surface or a bottom surface of the substrate body 111. In one or more embodiments, the first surface 111U and the second surface 111B of the substrate body 111 may extend substantially along a plane defined by a first direction D1 and a second direction D2, and may be spaced apart from each other in a third direction D3. For example, the first direction D1 and the second direction D2 may be parallel or substantially parallel to the first surface 111U or the second surface 111B of the substrate body 111, and intersect with each other (e.g., be perpendicular to each other). The third direction D3 may intersect with the first direction D1 and the second direction D2 (e.g., be perpendicular to the first direction D1 and the second direction D2). For example, the third direction D3 may be perpendicular or substantially perpendicular to the first surface 111U or the second surface 111B of the substrate body 111. In some embodiments, the third direction D3 may refer to a thickness direction of the substrate body 111.

The substrate connector 113 may be disposed on the first surface 111U of the substrate body 111, and the substrate connection terminal 112 may be disposed on the second surface 111B of the substrate body 111.

The substrate connector 113 may be used for an electrical connection with the semiconductor chip 120. The substrate connector 113 may be disposed in an upper portion of the substrate body 111. The substrate connector 113 may be exposed at the first surface 111U of the substrate body 111. In one or more embodiments, the substrate connector 113 may protrude above the first surface 111U of the substrate body 111. When the substrate connector 113 protrudes from the first surface 111U of the substrate body 111, the reliability of the connection between the substrate connector 113 and a chip connection terminal 123 to be described later of the semiconductor chip 120 may be improved. In one or more embodiments, the substrate connector 113 may include or be formed of a metal material. For example, the substrate connector 113 may include or be formed of copper (Cu), but is not limited thereto. In one or more embodiments, the substrate connector 113 may be a trace or a conductive bump. For example, the substrate connector 113 may be a copper trace.

The substrate connection terminal 112 may be used to electrically connect the semiconductor package 100 to the outside of the semiconductor package 100. The substrate connection terminal 112 may be attached to the second surface 111B of the substrate body 111. In one or more embodiments, the substrate connection terminal 112 may include or be formed of solder. For example, the substrate connection terminal 112 may be a solder ball. However, as understood by one of ordinary skill in the art, the embodiments are not limited thereto.

The substrate connector 113 and the substrate connection terminal 112 may be connected through a conductive path disposed inside the substrate body 111, so as to electrically communicate with each other. In one or more embodiments, the conductive path of the substrate body 111 may be formed of one or more conductive wirings and one or more conductive vias formed or arranged in the substrate body 111, or through any other suitable connection mechanisms known to one of ordinary skill in the art.

In one or more examples, the semiconductor package 100 may include a plurality of substrate connectors 113. The plurality of substrate connectors 113 may be distributed on the first surface 111U of the substrate body 111 with a predetermined arrangement. For example, the plurality of substrate connectors 113 may be arranged on the first surface 111U of the substrate body 111 in correspondence with a plurality of chip connection terminals 123 to be described later of the semiconductor chip 120, so as to allow each of the plurality of chip connection terminals 123 to be electrically connected to the internal conductive paths of the substrate body 111 through a corresponding one of the substrate connectors 113. In one or more examples, each of the substrate connectors 113 may be spaced equally apart from each other. In one or more examples, a distance between at least a first substrate connector from among the plurality of substrate connectors and a second substrate connector from among the plurality of substrate connectors may be different than a distance between the remaining substrate connectors from among the plurality of substrate connectors.

In one or more examples, the semiconductor package 100 may include a plurality of substrate connection terminals 112. The plurality of substrate connectors 112 may be distributed on the second surface 111B of the substrate body 111 in accordance with a predetermined arrangement. The distribution of the plurality of substrate connection terminals 112 may vary depending on a specification of an external component (e.g., a main board or another substrate) to which the semiconductor package 100 is to be connected. In one or more embodiments, the plurality of substrate connection terminals 112 may be arranged in a form of a Ball Grid Array (BGA) or a Fine-Pitch Ball Grid Array (FBGA), but are not limited thereto. In one or more examples, the plurality of substrate connection terminals 112 may be connected to the plurality of internal conductive paths of the substrate body 111, respectively, to be electrically connected to the plurality of substrate connectors 113, respectively. As such, the substrate 110 including the substrate body 111, the substrate connection terminals 112, and the substrate connectors 113 may provide support for the semiconductor chip 120 disposed thereon, while being used to fan-in or fan-out the semiconductor chip 120 to the outside of the semiconductor package 100. For example, in one or more embodiments, the semiconductor package 100 may be attached to an external substrate, such as a printed circuit board (PCB), by using the substrate connection terminal 112 of the substrate 110 through a surface mounting technology (SMT).

In one or more examples, the semiconductor chip 120 may be disposed on the first surface 111U of the substrate body 111. The semiconductor chip 120 may be disposed in a flip-chip form. The semiconductor chip 120 may include a chip body 121, a chip pad 122 coupled to the chip body 121, and a chip connection terminal 123 coupled to the chip pad 122.

The chip body 121 may include a semiconductor material, for example, but not limited to, silicon (Si), germanium (Ge), or silicon-germanium (SiGe). The chip body 121 may be formed thereinside with circuits for performing a logic function, a storage function, and/or any other suitable function known to one of ordinary skill in the art, and the associated connections thereof. The chip body 121 may be a die, for example, an unpackaged wafer. The chip body 121 may be any suitable type of a die, for example, but not limited to, a logic die, a memory die, or any other suitable structure known to one of ordinary skill in the art. The chip body 121 may have a first surface 121U and a second surface 121B opposite to each other in the third direction D3. As used herein, the third direction D3 may also be a thickness direction of the chip body 121. For example, when the chip body 121 is substantially flat, the thickness direction of the chip body 121 may be perpendicular or substantially perpendicular to the first surface 121U or the second surface 121B of the chip body 121, and/or parallel or substantially parallel to the thickness direction of the substrate body 111.

The chip pad 122 may be disposed on the second surface 121B of the chip body 121, and electrically connected to a circuit formed inside the chip body 121. Accordingly, the second surface 121B of the chip body 121 may be referred to as an active surface, while the first surface 121U of the chip body 121 may be referred to as a passive surface. The chip pad 122 may be exposed on the second surface 121B of the chip body 121. In one or more embodiments, the chip pad 122 may protrude above (e.g., “below” in FIG. 1A) the second surface 121B of the chip body 121. When the chip pad 122 protrudes from the second surface 121B of the chip body 121, the reliability of the connection between the chip pad 122 and the chip connection terminal 123 may be improved. The chip pad 122 may include or be formed of a metal material. For example, the chip pad 122 may include a metal, a metal alloy, and/or a conductive metal nitride. In one or more embodiments, the chip pad 122 may have a single-layer or multi-layer structure. In one or more embodiments, the chip pad 122 may be a conductive bump (e.g., micro-bump).

The chip connection terminal 123 may be disposed on the chip pad 122, with the chip pad 122 interposed therebetween. The chip connection terminal 123 may be connected to the chip pad 122, and electrically connected to the chip body 121 (e.g., the internal circuit of the chip body 121) via the chip pad 122. In one or more embodiments, the chip connection terminal 123 may include or be formed of solder. For example, the chip connection terminal 123 may be solder formed on a bump and used for a bump connection. In some embodiments, as illustrated, the chip connection terminal 123 may have a ball shape. However, the shape of the chip connection terminal 123 is not limited thereto, and for example, the chip connection terminal 123 may have any other suitable shape known to one of ordinary skill in the art. The chip connection terminal 123 may be used to electrically connect the internal circuit of the chip body 121 to the outside of the semiconductor chip 120. For example, the semiconductor chip 120 may be electrically connected to the substrate 110 (e.g., the substrate body 111) through the chip connection terminal 123. For example, the chip connection terminal 123 of the semiconductor chip 120 may be coupled and electrically connected with the substrate connector 113 of the substrate 110.

As illustrated in FIG. 1A, the second surface 121B (e.g., the active surface) of the chip body 121 may face the first surface 111U of the substrate body 111, such that the chip connection terminal 123 and the substrate connectors 113 may face and/or overlap each other (e.g., in the third direction D3). In the semiconductor package 100, the chip connection terminal 123 and the substrate connector 113 facing and/or overlapping each other may be in contact with and coupled to each other. In one or more embodiments, by a flip-chip process, the semiconductor chip 120 may be mounted on the substrate 110, while the chip connection terminal 123 is coupled to the substrate connector 113. During the flip-chip process, the chip connection terminal 123 may remove an organic protection layer formed at a surface of the substrate connector 113 in contact with the chip connection terminal 123 by wetting the surface of the substrate connector 113, and then be coupled to the substrate connector 113 by reflow soldering, thereby forming an electrical connection with the substrate connector 113. As a result, the semiconductor chip 120 (e.g., the chip body 121) may be disposed on the substrate 110 (e.g., the substrate body 111) in the flip-chip form and electrically communicated therewith. The semiconductor chip 120 may be fanned-in or fanned-out to the outside of the semiconductor package 100 through the substrate 110.

In one or more examples, the chip pads 122 and the chip connection terminals 123 may be disposed in one-to-one. For example, the chip pads 122 may have any suitable number and arrangement depending on the electrical connection need of the chip body 121. For example, the chip connection terminals 123 may have any suitable number and arrangement depending on the number and arrangement of the chip pads 122. In one or more examples, the substrate connectors 113 as described above may also have a number and arrangement corresponding to the numbers and arrangements of the chip pads 122 and the chip connection terminals 123. However, the embodiments are not limited thereto. For example, the numbers and arrangements of the chip pads 122, the chip connection terminals 123, and the substrate connectors 113 may variously vary depending on the embodiments.

According to the example embodiments of the present disclosure, referring to FIGS. 1A through 1C, the substrate 110 may further include a substrate extension part 114, and the semiconductor chip 120 may further include a chip extension part 124. The substrate extension part 114 and the chip extension part 124 may be disposed in correspondence with each other, for example, overlap each other in the third direction D3. In one or more embodiments, the substrate extension part 114 and the chip extension part 124 may have the same or different shapes in a plan view (e.g., a plane defined by the first direction D1 and the second direction D2). In one or more embodiments, the substrate extension part 114 may have an integral structure or include a plurality of portions separated from each other. The chip extension part 124 may have an integral structure or include a plurality of portions separated from each other. When the substrate extension part 114 and the chip extension part 124 each include a plurality of portions, the number of the plurality of portions of the substrate extension part 114 and the number of the plurality of portions of the chip extension part 124 may be the same as or different from each other.

Referring to FIGS. 1A and 1B, the substrate extension part 114 may be disposed on the first surface 111U of the substrate body 111. The substrate extension part 114 may be attached to the first surface 111U of the substrate body 111. The substrate extension part 114 may be electrically insulated from the substrate body 111. When the substrate body 111 is an insulating substrate, the substrate extension part 114 may be disposed directly on the substrate body 111. When the substrate body 111 is a non-insulating substrate (e.g., a metal substrate), an additional insulating layer may be disposed between the substrate extension part 114 and the substrate body 111, to electrically insulate the substrate extension part 114 and the substrate body 111 from each other. For example, the additional insulating layer may include an insulating material, such as silicon oxide. In one or more embodiments, for example, the additional insulating layer may be formed by depositing the insulating material on the first surface 111U of the substrate body 111 before the substrate extension part 114 is disposed.

As illustrated in FIG. 1B, the substrate body 111 may have a connector region CR. The connector region CR may be located at the first surface 111U. The connector region CR may overlap the chip body 121 in the third direction D3. The substrate connectors 113 may be located in the connector region CR. In one or more embodiments, the substrate connectors 113 may be exposed at the first surface 111U of the substrate body 111 in the connector region CR. In one or more embodiments, the substrate connectors 113 may protrude above the first surface 111U of the substrate body 111 in the connector region CR. Referring to FIG. 1B, the substrate extension part 114 may be disposed around the connector region CR in a plan view. For example, the substrate extension part 114 may surround the connector region CR in a plan view. As illustrated in FIG. 1B, the substrate extension part 114 may completely surround the connector region CR. However, the embodiments are not limited thereto. For example, as to be described later, the substrate extension part 114 may partially surround the connector region CR. In one or more examples, as illustrated in FIGS. 1A and 1B, the substrate extension part 114 may be disposed outside the connector region CR. For example, the substrate extension part 114 may be closer to an outer edge of the substrate body 111 than the substrate connectors 113.

In one or more examples, the substrate extension part 114 may be spaced apart and electrically isolated from the substrate connectors 113. For example, the substrate extension part 114 may be spaced apart from the substrate connectors 113 located in the connector region CR, around the connector region CR. In one or more examples, the substrate extension part 114 may be spaced apart and electrically isolated from the semiconductor chip 120. For example, the substrate extension part 114 may be spaced apart and electrically isolated from the chip connection terminals 123 coupled to the substrate connectors 113. For example, the substrate extension part 114 may be spaced apart from the chip connection terminals 123 located on the second surface 121B of the chip body 121, at a periphery of the chip body 121. In one or more embodiments, an additional insulating material may be disposed between the substrate extension part 114, and the substrate connectors 113 and/or the chip connection terminals 123 adjacent thereto (e.g., in the first direction D1 and/or the second direction D2). In one or more embodiments, as illustrated in FIG. 1A, the additional insulating material may be a portion of a mold layer 130 to be described later.

In one or more examples, the substrate extension part 114 may include a first magnetic material. For example, the substrate extension part 114 may be formed of the first magnetic material. The first magnetic material included in the substrate extension part 114 may make the substrate extension part 114 have a first magnetism. In one or more embodiments, the first magnetic material may include iron (Fe), cobalt (Co), nickel (Ni), or an alloy thereof, a rare earth element or an alloy thereof, etc. For example, the first magnetic material may include iron (Fe), cobalt (Co), nickel (Ni), or an alloy thereof. In some embodiments, the substrate extension part 114 may further include a first resin. For example, the substrate extension part 114 may be formed of the first magnetic material and the first resin, and the first magnetic material may be dispersed in the first resin. In this case, the first magnetic material may be in a form of a magnetic filler (e.g., magnetic particles). The first resin may include or may be an insulating material, such as epoxy resin or any other suitable material known to one of ordinary skill in the art. When the substrate extension part 114 is formed of the first magnetic material and the first resin, the additional insulating layer described above may be omitted even if the substrate body 111 is a non-insulating substrate. In one or more examples, depending on the material, shape, size, and/or any other parameter, of the substrate extension part 114, the substrate extension part 114 may be disposed on the first surface 111U of the substrate body 111 by any suitable method, such as electroplating, printing, attaching, or any other known method known to one of ordinary skill in the art.

Referring to FIGS. 1A and 1C, the chip extension part 124 may be disposed on a side surface 121S of the chip body 121. The chip extension part 124 may overlap the chip body 121 in a direction perpendicular to the thickness direction of the chip body 121. The chip extension part 124 may cover the side surface 121S of the chip body 121. The chip extension part 124 may be in contact with the side surface 121S of the chip body 121. The chip extension part 124 may be electrically insulated from the chip body 121. As described herein, the side surface 121S of the chip body 121 may be at least a portion of an outer side surface of the chip body 121, where the outer side surface of the chip body 121 may connect the first surface 121U and the second surface 121B of the chip body 121, and constitute an outer profile of the chip body 121 together with the first surface 121U and the second surface 121B. Taking the embodiment of FIGS. 1A through 1C as an example, the side surface 121S of the chip body 121 may be the entirety of the outer side surface of the chip body 121, such as an outer side surface in each of the first direction D1 and the second direction D2.

As illustrated in FIG. 1A, the chip extension part 124 may completely overlap the chip body 121 in a direction perpendicular to the third direction D3 (e.g., parallel to the first direction D1 and/or the second direction D2). The chip extension part 124 may completely cover the side surface 121S of the chip body 121 along the third direction D3 such that the side surface 121S remains unexposed. The chip extension part 124 may have a thickness substantially the same as that of the chip body 121 in the third direction D3. Upper and lower surfaces of the chip extension part 124 may be substantially coplanar with the first surface 121U and the second surface 121B of the chip body 121, respectively. However, the embodiments are not limited thereto. For example, in some embodiments, the chip extension part 124 may overlap a portion of the chip body 121 in the direction perpendicular to the third direction D3, and the chip extension part 124 may cover only a portion of the side surface 121S of the chip body 121 along the third direction D3. In some embodiments, the thickness of the chip extension part 124 may be different from the thickness of the chip body 121. In the case where the thickness of the chip extension part 124 and the thickness of the chip body 121 are different from each other, the upper surface of the chip extension part 124 may be substantially coplanar with the first surface 121U of the chip body 121, and the lower surface of the chip extension part 124 may be at a level different from (e.g., higher or lower than) the second surface 121B of the chip body 121 in the third direction D3, but is not limited thereto.

In a plan view, the chip extension part 124 may be disposed around the chip body 121. For example, in a plan view, the chip extension part 124 may surround the chip body 121. As an example, as illustrated in FIG. 1C, the chip extension part 124 may completely surround the chip body 121, but is not limited thereto. For example, in some embodiments, the chip extension part 124 may partially surround the chip body 121 in a plan view.

In one or more examples, as illustrated in FIGS. 1A and 1C, the chip extension part 124 may not cover the first surface 121U and the second surface 121B of the chip body 121. In some embodiments, all the side surfaces 121S of the chip body 121 may be covered with the chip extension part 124 without being exposed to the outside. In this case, an outer side surface of the chip extension part 124 may constitute an outer side surface of the semiconductor chip 120. In some other embodiments, a portion of the side surface 121S of the chip body 121 may be exposed by the chip extension part 124 without being covered with the chip extension part 124. In this case, the outer side surface of the chip extension part 124 may constitute the outer side surface of the semiconductor chip 120, together with the outer side surface of the chip body 121 that is not covered with the chip extension part 124.

The chip extension part 124 may include a second magnetic material 124-a. The second magnetic material 124-a included in the chip extension part 124 may make the chip extension part 124 have a second magnetism. In one or more embodiments, the second magnetic material 124-a may include iron (Fe), cobalt (Co), nickel (Ni), or an alloy thereof, a rare earth element or an alloy thereof, etc. For example, the second magnetic material 124-a may include iron (Fe), cobalt (Co), nickel (Ni), or an alloy thereof. In one or more embodiments, the chip extension part 124 may further include a second resin 124-b. For example, the chip extension part 124 may be formed of the second magnetic material 124-a and the second resin 124-b, and the second magnetic material 124-a may be dispersed in the second resin 124-b. The second magnetic material 124-a dispersed in the second resin 124-b may be in a form of a magnetic filler (e.g., magnetic particles). The second resin 124-b may include or may be an insulating material, such as epoxy resin, or any other suitable material known to one of ordinary skill in the art.

Referring to FIGS. 1A through 1C, the semiconductor chip 120 and the substrate 110 may overlap in the third direction D3, and the chip extension part 124 and the substrate extension part 114 may overlap in the third direction D3. In one or more embodiments, as illustrated in FIG. 1A, the chip extension part 124 and the substrate extension part 114 may completely overlap in the third direction D3, but are not limited thereto. For example, the chip extension part 124 and the substrate extension part 114 may partially overlap in the third direction D3.

In one or more examples, the chip extension part 124 and the substrate extension part 114 may be spaced apart from each other and not in contact with each other in the third direction D3. In one or more embodiments, as illustrated in FIG. 1A, the chip extension part 124 and the substrate extension part 114 may also not overlap in the first direction D1 and the second direction D2. However, the embodiments are not limited to these extensions. The chip extension part 124 and the substrate extension part 114 overlapping each other may be spaced apart from and not in contact with each other. For example, there may be a specific or predetermined gap between the chip extension part 124 and the substrate extension part 114. The specific or predetermined gap between the chip extension part 124 and the substrate extension part 114 is not particularly limited, and may be variously changed depending on, for example, a designed interval between the chip body 121 and the substrate body 111, a required magnitude of a magnetic force generated between the chip extension part 124 and the substrate extension part 114 to be described later, etc.

Referring again to FIG. 1A, the semiconductor package 100 may further include a mold layer 130. The mold layer 130 may encapsulate the semiconductor chip 120 on the first surface 111U of the substrate body 111. The mold layer 130 may cover an upper surface and the outer side surface of the semiconductor chip 120 and an upper surface of the substrate 110 not overlapping the semiconductor chip 120. For example, as illustrated in FIG. 1A, the mold layer 130 may cover the second surface 121U of the chip body 121, the upper and side surfaces of the chip extension part 124, and a portion of the first surface 111U of the substrate body 111 not overlapping the semiconductor chip 120 in the third direction D3. In one or more examples, the mold layer 130 may also fill (e.g., completely fill) a space between the chip body 121 and the substrate body 111 and a space between the chip extension part 124 and the substrate extension part 114. For example, the mold layer 130 may cover the lower surface of the chip extension part 124, may cover the upper and side surfaces of the substrate extension part 114, and may surround the chip connection terminal 123. When the chip pad 122 has a portion protruding from the second surface 121B of the chip body 121, the mold layer 130 may also surround the protruding portion of the chip pad 122. When the substrate connector 113 has a portion protruding from the first surface 111U of the substrate body 111, the mold layer 130 may also surround the protruding portion of the substrate connector 113.

As illustrated in FIG. 1A, a side surface of the mold layer 130 may be substantially coplanar with a side surface of the substrate body 111. However, the embodiments are not limited to this configuration. In some embodiments, the mold layer 130 may extend beyond the side surface of the substrate body 111 in the first direction D1 and/or the second direction D2, and may also extend in the third direction D3 to cover the side surface of the substrate body 111.

In one or more embodiments, the mold layer 130 may include, or be formed of, a molding material or an under-fill. For example, the molding material may include or may be an epoxy molding compound (EMC). For example, the under-fill may include or may be a thermal- or light-curable resin with or without a filler therein.

As described above, the substrate extension part 114 including the first magnetic material may have the first magnetism, and the chip extension part 124 including the second magnetic material 124-a may have the second magnetism. The first magnetism of the substrate extension part 114 and the second magnetism of the chip extension part 124 may be the same as each other or different from each other. When the first magnetism of the substrate extension part 114 and the second magnetism of the chip extension part 124 are different from each other, a magnetic attraction force may be generated between the substrate extension part 114 and the chip extension part 124 overlapping each other. When the first magnetism of the substrate extension part 114 and the second magnetism of the chip extension part 124 are the same as each other, a magnetic repulsion force may be generated between the substrate extension part 114 and the chip extension part 124 overlapping each other. The magnetic attraction force or the magnetic repulsion force (i.e., a magnetic force) generated between the substrate extension part 114 and the chip extension part 124 may be used to correct a warpage of the chip body 121, which will be described in detail below.

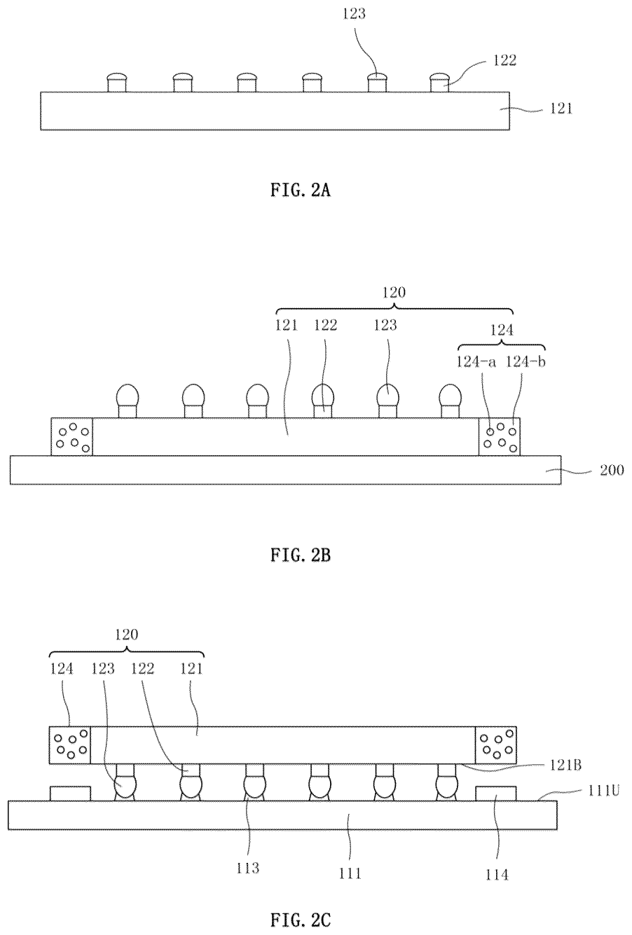

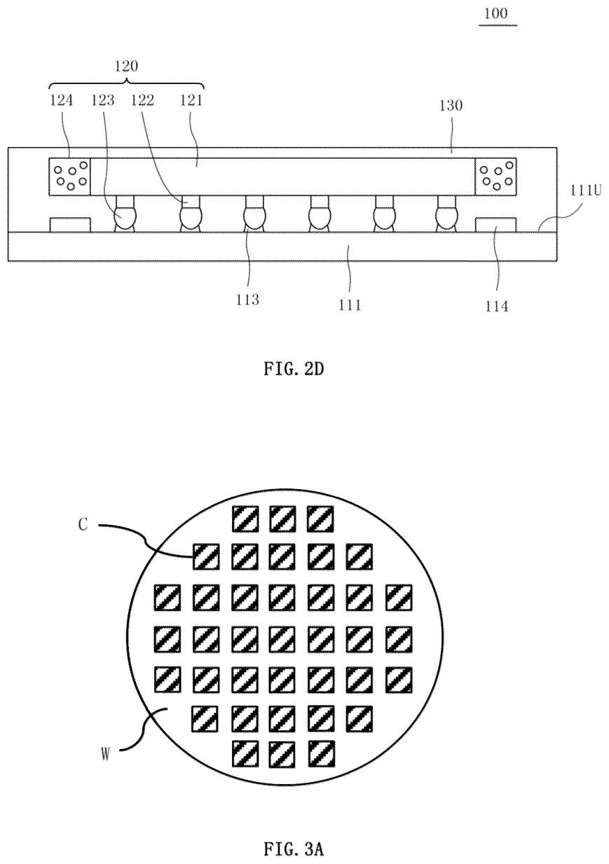

Hereinabove, the examples of the semiconductor package according to some embodiments have been described with reference to FIGS. 1A through 1C. Examples of a method of manufacturing the semiconductor package 100 of FIGS. 1A through 1C will be described below with reference to FIGS. 2A through 2D.

FIGS. 2A through 2D are schematic diagrams illustrating intermediate steps of a method of manufacturing a semiconductor package according to some embodiments. For ease of description, the same or similar reference numerals are used to denote components that are the same as or similar to those of FIGS. 1A through 1C, and redundant descriptions thereof may be omitted.

Referring to FIG. 2A, in one or more examples, a chip body 121 may be prepared. Herein, the chip body 121 may be any type of finished die that is manufactured in advance through semiconductor processes. The chip body 121 may have chip pads 122 formed on an active surface (“upper surface” in FIG. 2A) thereof. Chip connection terminals 123 may be coupled to the chip pads 122, and the chip pads 122 may be between the chip body 121 and the chip connection terminals 123 to electrically connect the chip body 121 to the chip connection terminals 123.

Referring to FIG. 2B, in one or more examples, the chip body 121 having the chip pads 122 and the chip connection terminals 123 may be fixed to a carrier plate 200. For example, the chip body 121 may be adhered to the carrier plate 200 through a removable adhesive film, but is not limited thereto. When the chip body 121 is fixed to the carrier plate 200, a passive surface (“lower surface” in FIG. 2B) of the chip body 121 may face the carrier plate 200.

Thereafter, a chip extension part 124 having a second magnetism may be formed on side surfaces 121S of the chip body 121 through a molding process. For example, a preliminary resin material and a magnetic particle material may be prepared. Herein, the preliminary resin material may be an uncured epoxy resin material, and the magnetic particle material may be a particle material formed from a magnetic material including iron (Fe), cobalt (Co), nickel (Ni), or an alloy thereof, a rare earth element, or an alloy thereof, etc., and may exhibit the same magnetism as the second magnetism of the chip extension part 124. Then, the magnetic particle material may be dispersed in the preliminary resin material to prepare a pre-molding material, the pre-molding material may be applied onto the carrier plate 200 and come in contact with the side surfaces 121S of the chip body 121, and the pre-molding material may be cured. As a result, the chip extension part 124 including the second resin 124-b and the second magnetic material 124-a dispersed therein may be formed, where the second resin 124-b may be formed from the cured preliminary resin material, and the second magnetic material 124-a may be formed from the dispersed magnetic particle material.

According to the size (e.g., a thickness in the third direction D3 and/or a width in the first direction D1 and/or the third direction D3), shape (e.g., a continuous single body or a plurality of portions separated from each other), position (e.g., partially or completely surrounding the chip body 121), or any other dimension, of the chip extension part 124 desired to be formed, the applying amount, the applying form, and the applying position of the pre-molding material may be adjusted to form the desired chip extension part 124.

In some embodiments, after the pre-molding material is cured, a trimming process may additionally be performed to adjust the size, shape, and position of the cured pre-molding material. As such, the desired chip extension part 124 may be formed more easily. Herein, the trimming process may include, but not limited to, grinding, cutting, or any other suitable trimming process known to one of ordinary skill in the art.

In some embodiments, before forming the chip extension part 124, a protection layer may be formed to cover the active surface of the chip body 121 and the chip pads 122 and the chip connection terminals 123 thereon, and after forming the chip extension part 124, the protection layer may be removed to expose the active surface of the chip body 121, the chip pads 122, and the chip connection terminals 123 again. The protection layer may protect the chip body 121, the chip pads 122, and the chip connection terminals 123 from being damaged during the process of forming the chip extension part 124. As an example, a photoresist layer may be used as the protection layer, but is not limited thereto.

After the chip extension part 134 is formed, the carrier plate 200 and the adhesive film for adhering may be removed, thereby obtaining the semiconductor chip 120.

Referring to FIG. 2C, in one or more examples, a substrate body 111 may be prepared. The substrate body 111 may be an insulating substrate or a non-insulating substrate. The substrate body 111 may be formed with substrate connectors 113 at an upper surface (e.g., the first surface 111U) thereof. Then, a substrate extension part 114 may be formed at a predetermined position of the first surface 111U of the substrate body 111. As described above with reference to FIGS. 1A through 1C, the predetermined position at which the substrate extension part 114 is formed may be outside a connector region CR (see FIG. 1B) of the substrate body 111 in which the substrate connectors 113 are disposed, and may correspond to a position of the chip extension part 124 of the semiconductor chip 120 to be disposed on the substrate body 111. For example, the predetermined position may be determined such that the substrate extension part 114 and the chip extension part 124 overlap in a direction (e.g., the third direction D3 in FIGS. 1A through 1C), in which the semiconductor chip 120 and the substrate body overlap when the semiconductor chip 120 is mounted on the substrate body 111.

In some embodiments, the substrate extension part 114 having the first magnetism may be formed on the first surface 111U of the substrate body 111 by using a magnetic material including, for example, iron (Fe), cobalt (Co), nickel (Ni), or an alloy thereof, a rare earth element or an alloy thereof, etc., through an electroplating process, but is not limited thereto. In some embodiments, the substrate extension part 114 having the first magnetism may be formed by using a pre-molding material including a magnetic particle material and a preliminary resin material through a molding process. Except that the magnetic particle material included in the pre-molding material may exhibit the same magnetism as the first magnetism of the substrate extension part 114, the pre-molding material and the molding process used to form the substrate extension part 114 may be similar to the pre-molding material and the molding process used to form the chip extension part 124 described above with reference to FIG. 2B, and thus, redundant descriptions thereof may be omitted. In some embodiments, the substrate extension part 114 may be separately formed as an individual component, and the substrate extension part 114 formed as the individual component may then be attached or fixed to the predetermined position of the first surface 111U of the substrate body 111. However, the embodiments are not limited these configurations.

Furthermore, the size, shape, and/or position of the substrate extension part 114 formed herein may be controlled according to the size, shape, and/or position of the chip extension part 124 without any particular limit, as long as the formed substrate extension part 114 and the chip extension part 124 satisfy the arrangement relationship described above with reference to FIGS. 1A through 1C and generate a desired magnetic force therebetween.

Thereafter, the semiconductor chip 120 obtained in the process described with reference to FIGS. 2A and 2B may be mounted to the substrate body 111. Herein, the semiconductor chip 120 may be mounted to the substrate body 111 by a flip-chip technology. Specifically, the semiconductor chip 120 may be placed on the substrate body 111, such that the active surface (e.g., the second surface 121B) of the chip body 121 of the semiconductor chip 120 may face the first surface 111U of the substrate body 111, and the chip connection terminals 123 of the semiconductor chip 120 may contact the substrate connectors 113 of the substrate body 111.

As illustrated in FIG. 2C, when the semiconductor chip 120 is placed on the substrate body 111, the chip extension part 124 and the substrate extension part 114 may overlap in the third direction D3 and thus, generate a magnetic force therebetween. The generated magnetic force may be used to correct a warpage of the chip body 121. Since the warpage of the chip body 121 is corrected, the difference in warpage between the chip body 121 and the substrate body 111 may be reduced or eliminated, thereby ensuring an effective contact between the chip connection terminal 123 and the substrate connector 113. Thus, a non-wet defect in which the chip connection terminal 123 may not effectively wet the substrate connector 113 may be reduced or prevented.

Subsequently, reflow soldering may be performed to connect the chip connection terminals 123 to the substrate connectors 113, thereby completing the mounting of the semiconductor chip 120 to the substrate body 111. Since the warpage of the chip body 121 is corrected before performing reflow soldering, and the non-wet defect between the chip connection terminal 123 and the substrate connector 113 is reduced or prevented, an electrical connection defect, such as disconnection or virtual soldering, between the chip connection terminal 123 and the substrate connector 113, which may occur after undergoing the reflow soldering, may be reduced or prevented.

Referring to FIG. 2D, in one or more examples, after the semiconductor chip 120 is mounted to the substrate body 111, a mold layer 130 may be formed on the substrate body 111 (e.g., the first surface 111U of the substrate body 111) to encapsulate the semiconductor chip 120. The mold layer 130 described herein may be the same as or similar to the mold layer 130 described with reference to FIGS. 1A through 1C, and thus, redundant descriptions thereof may be omitted.

Thereafter, referring back to FIG. 1A, substrate connection terminals 112 may be disposed on the second surface 111B of the substrate body 111 of the obtained structure of FIG. 2D. In one or more embodiments, the substrate connection terminals 112 may be solder balls. The substrate connection terminals 112 may be formed on the second surface 111B of the substrate body 111 by a ball-planting process to have a predetermined arrangement. In one or more examples, the substrate connection terminals 112 described herein may be the same as or similar to the substrate connection terminals 112 described with reference to FIGS. 1A through 1C, and thus, redundant descriptions thereof may be omitted.

As a result, the semiconductor package 100 with reference to FIGS. 1A through 1C may be manufactured.

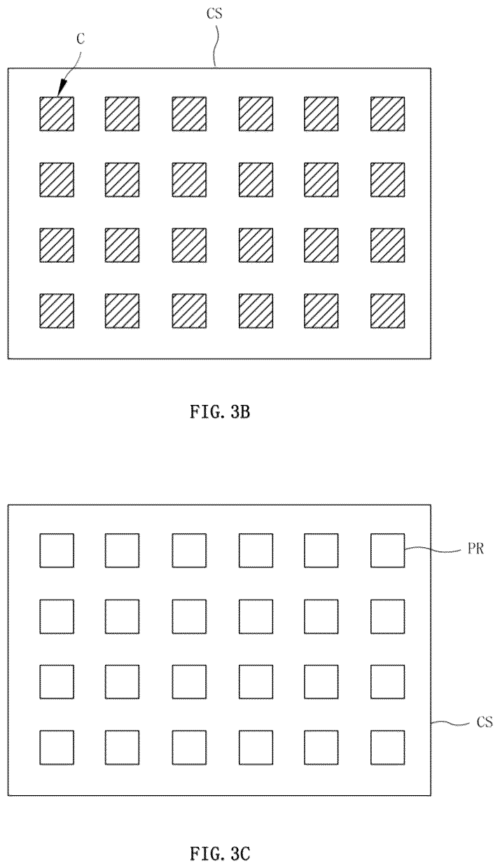

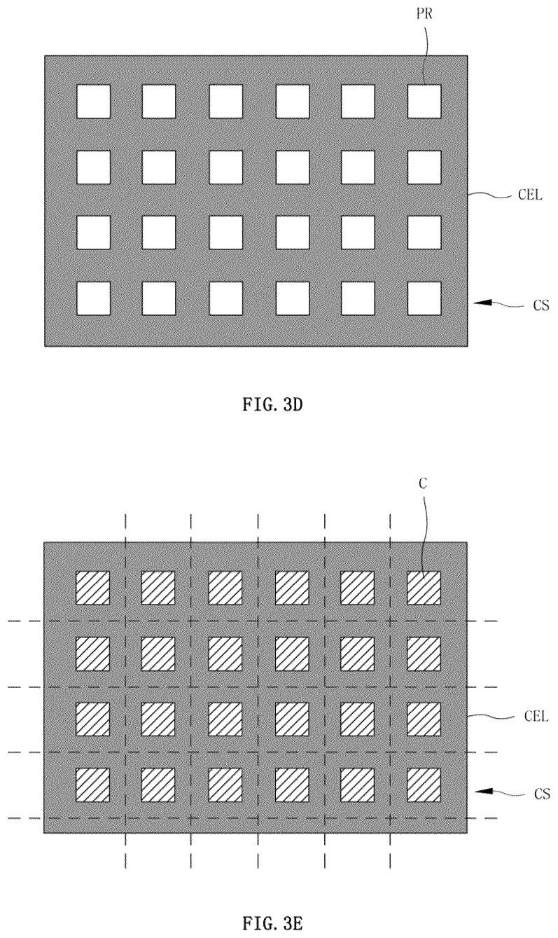

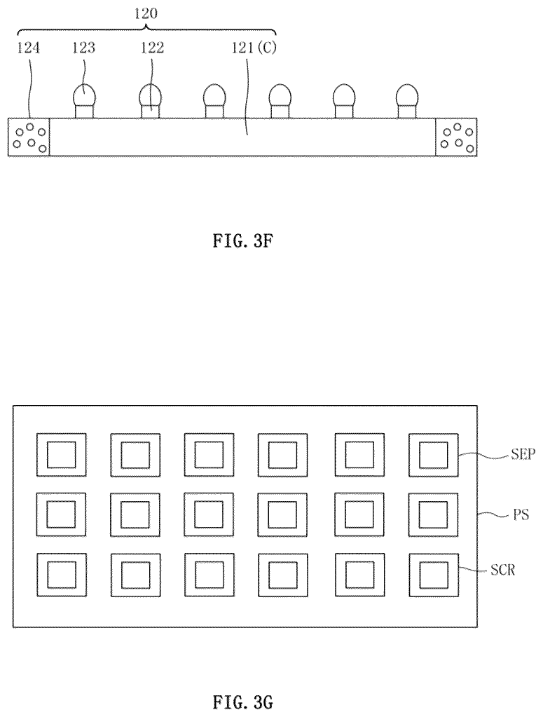

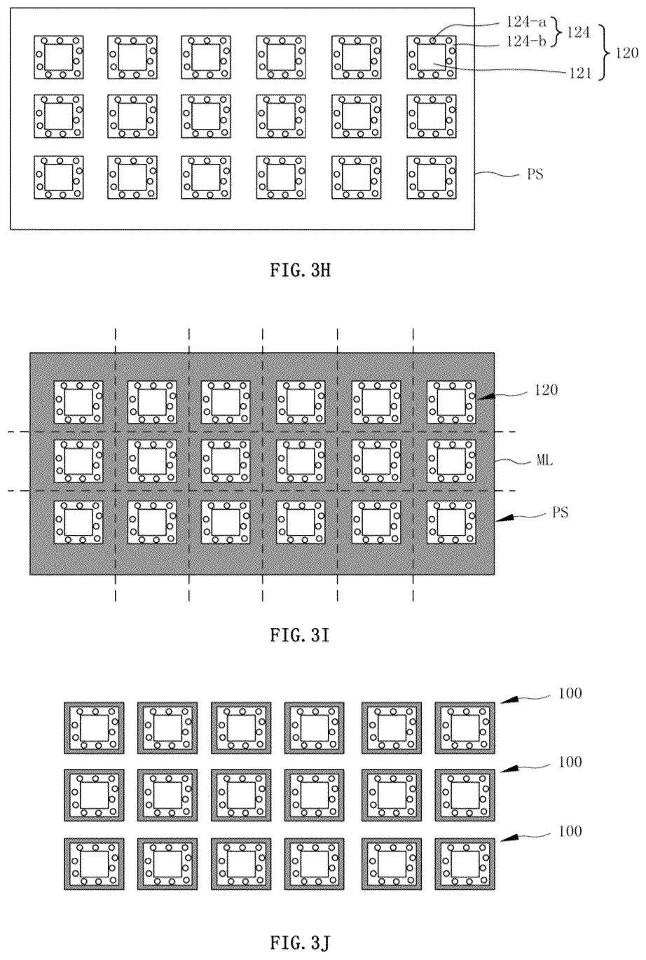

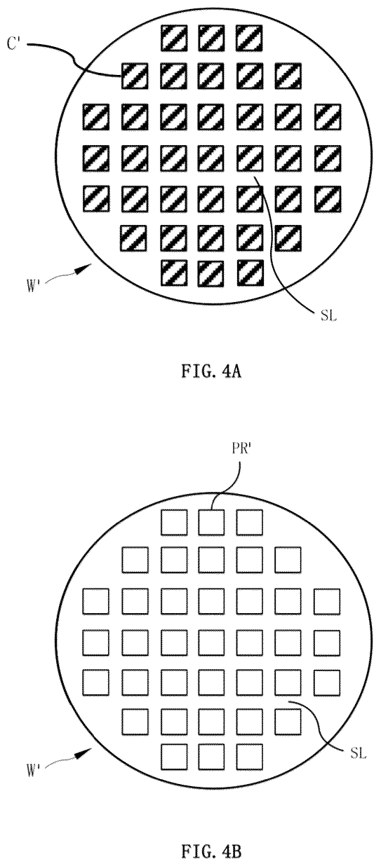

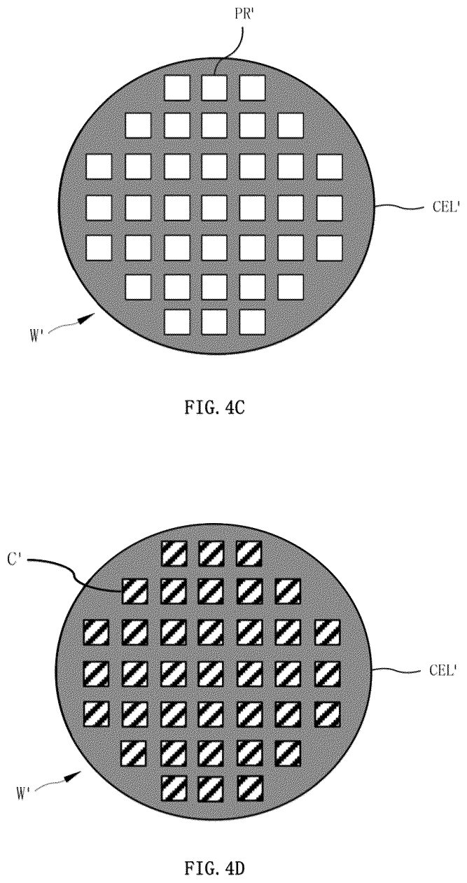

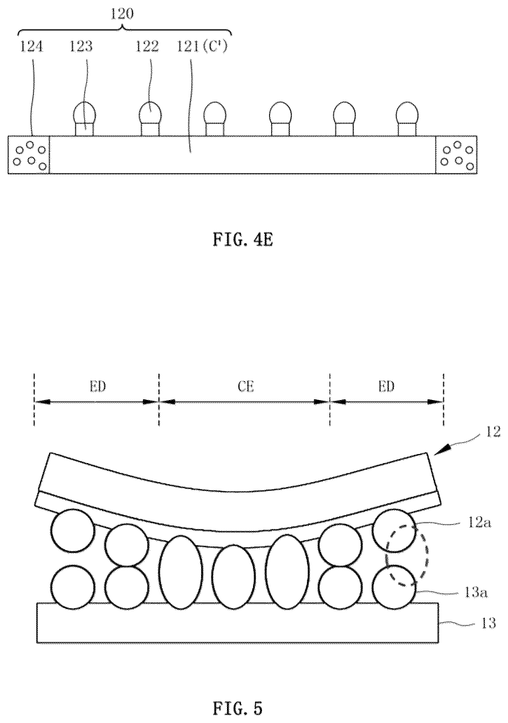

Hereinabove, the example method of manufacturing the semiconductor package 100 has been described with reference to FIGS. 2A through 2D, together with FIGS. 1A through 1C. However, the embodiments are not limited thereto. Hereinafter, a batch manufacturing method for the semiconductor package 100 will be described in conjunction with FIGS. 3A through 3J and FIGS. 4A through 4E. For ease of description, the same or similar reference numerals are used to denote components that are the same as or similar to those of FIGS. 1A through 1C and FIGS. 2A through 2D, and redundant descriptions thereof may be omitted.

FIGS. 3A through 3J are schematic diagrams illustrating intermediate steps of a method of manufacturing a semiconductor package according to some embodiments.

Referring to FIG. 3A, in one or more examples, a wafer W may be prepared. As illustrated in FIG. 3A, the wafer W may be a wafer that has been formed with a plurality of chips C therein, but not undergone a slicing process. In one or more embodiments, the wafer W may include a semiconductor substrate and an integrated circuit (e.g., circuit patterns) formed on the semiconductor substrate. The semiconductor substrate may be, for example, a silicon substrate, a germanium substrate, a silicon-germanium substrate, a silicon-on-insulator substrate, or a germanium-on-insulator substrate. The integrated circuit may be, for example, a circuit that performs a logic function, a storage function, and/or any other suitable function known to one of ordinary skill in the art, and may also include connections for circuits. In one or more embodiments, the integrated circuit may be formed on the semiconductor substrate by any suitable semiconductor manufacturing technology, such that the wafer W may be formed to include the plurality of chips C. Each of the plurality of chips C may include a portion of the semiconductor substrate and a portion of the integrated circuit, and have a specific or predetermined function. In one or more examples, pads and connection terminals for connecting the integrated circuit of each of the chips C to the outside may be formed on the active surface of the chip C. The process of forming the pads and the connecting terminals described herein may be any suitable process known in the art without a particular limit.

Subsequently, a slicing process may be performed on the wafer W to obtain a plurality of chips C separated from each other. In one or more embodiments, the wafer W may be sliced by processes, such as sawing, laser cutting, or any other suitable slicing process known to one of ordinary skill in the art, but is not limited thereto. After the slicing, the plurality of chips C may be formed into a plurality of separated dies, respectively. Accordingly, each of the plurality of chips C may correspond to a chip body 121 in FIG. 3F to be described later.

Next, referring to FIG. 3B, in one or more examples, the plurality of chips C may be attached to a hard carrier plate CS. In one or more embodiments, the chips C may be attached to the hard carrier plate CS in a form of passive surfaces of the chips C facing the hard carrier plate CS. In one or more embodiments, the chips C may be attached to the hard carrier plate CS by using a removable adhesive film. In one or more embodiments, the hard carrier plate CS may be any suitable rigid plate configured to carry and support in subsequent processes. As illustrated in FIG. 3B, the plurality of chips C disposed on the hard carrier plate CS may be spaced apart from each other by a specific or predetermined distance, such that a side surface of each of the chips C may be exposed.

Next, referring to FIG. 3C, in one or more examples, protection patterns PR may be formed on each of the plurality of chips C. The protection pattern PR may cover (e.g., completely cover) the chip C. The protection pattern PR may protect the chip C from being damaged in subsequent processes. For example, the protection patterns PR may be formed on the active surface of each of the chips C to protect the pads, the connection terminals, or any other components, of the chips C from being damaged in subsequent processes.

In one or more embodiments, the protection patterns PR may be formed from a photoresist. For example, a protection layer covering the plurality of chips C may be formed on the entire hard carrier plate CS by using a photoresist, and then, may be performed with exposure and development. Through the exposure and development, portions of the protection layer covering the chips C may remain on the chips C, thereby forming the protection patterns PR. After the protection patterns PR are formed, the side surface of each of the plurality of chips C may be exposed again.

Next, referring to FIG. 3D, in one or more examples, a chip extension layer CEL may be formed on the hard carrier plate CS. The chip extension layer CEL may expose the protection patterns PR covering the chips C (see FIG. 3C), and may cover and contact the side surface of each of the chips C. For example, as illustrated in FIG. 3D, the chip extension layer CLE may surround each of the chips C, and be tightly coupled with the side surface of each of the chips C. Additionally, although not specifically illustrated, the chip extension layer CEL may be formed to have a thickness the same as or different from thicknesses of the chips C (see FIG. 3C).

The chip extension layer CEL may be formed of the same material as that of the chip extension part 124 described with reference to FIGS. 1A through 1C. The chip extension layer CEL may include the second magnetic material 124-a described with reference to FIGS. 1A through 1C, and in one or more embodiments, may further include the second resin 124-b described with reference to FIGS. 1A through 1C. In one or more embodiments, the second magnetic material 124-a as a magnetic filler may first be dispersed in an uncured epoxy resin material to prepare a resin slurry containing the magnetic filler. Thereafter, the prepared resin slurry may be coated on the hard carrier plate CS, and the resin slurry may then be cured, to form the chip extension layer CEL.

Next, referring to FIG. 3E, in one or more examples, the protection patterns PR (see FIG. 3D) may be removed to expose the chips C. In one or more examples, any suitable method may be used to remove the protection patterns PR, as long as the method does not damage the chips C.

Next, referring to FIG. 3F together with FIG. 3E, in one or more examples, cutting may be performed on the chip extension layer CEL, such that the plurality of chips C becomes individual again. For example, the chip extension layer CEL may be cut along virtual lines between the plurality of chips C, such that the chip extension layer CEL may be disconnected at the cut positions and separated into a plurality of portions (e.g., the chip extension parts 124) attached to different chips C. As illustrated in FIG. 3F, after the cutting is completed, the semiconductor chip 120 with reference to FIGS. 1A through 1C may be obtained, which includes a chip body 121 (e.g., the chip C), chip pads 122 and chip connection terminals 123 formed on an active surface of the chip body 121, and a chip extension part 124 formed on a side surface of the chip body 121.

In one or more embodiments, the hard carrier plate CS may be removed before cutting the chip extension layer CEL. However, the embodiments are not limited thereto. For example, the chip extension layer CEL and the hard carrier plate CS may be cut together, and the cut hard carrier plate CS attached to the semiconductor chip 120 may then be removed, to obtain the separate semiconductor chip 120.

Next, referring to FIG. 3G, in one or more examples, a substrate PS may be prepared. In one or more examples, the substrate PS may include a plurality of body portions corresponding to a plurality of substrate bodies 111 (see FIGS. 1A through 1C), respectively, and a connecting portion connecting the plurality of body portions as an integer. Each of the body portions of the substrate PS may have the same circuit configuration as the circuit configuration in the substrate body 111. The substrate PS may be separated into a plurality of substrate bodies 111 individual of each other by cutting the connecting portion of the substrate PS in a subsequent process. In one or more embodiments, the substrate PS described herein may be manufactured by a similar method to that of manufacturing the substrate body 111 as described above.

Subsequently, a substrate extension pattern SEP may be formed on the substrate PS. The substrate extension pattern SEP may be formed at a position of the substrate PS at which the semiconductor chip 120 (see FIG. 3D) is to be disposed. In other words, the substrate extension pattern SEP may be disposed around a substrate connector region SCR of the substrate PS corresponding to the connector region CR (see FIG. 1B) of the substrate body 111. As illustrated in FIG. 3G, in one or more examples, a plurality of substrate extension patterns SEP may be formed on the substrate PS. Each of the plurality of substrate extension patterns SEP may have a size and a shape corresponding to those of the chip extension part 124 of the semiconductor chip 120 described with reference to FIG. 3F, such that the substrate extension patterns SEP and the chip extension part 124 may overlap and be spaced apart from each other in a thickness direction of the substrate PS and/or the chip body 121 when the semiconductor chip 120 is disposed on the substrate PS. The descriptions of the substrate extension pattern SEP and the chip extension part 124 overlapping each other may be substantially the same as or similar to the descriptions of the substrate extension part 114 and the chip extension part 124 overlapping each other with reference to FIGS. 1A through 1C, and thus, redundant descriptions thereof may be omitted.

In one or more embodiments, the substrate extension pattern SEP may be formed of the first magnetic material as described above. In this case, the substrate extension pattern SEP may be formed on the substrate PS to have a predetermined size and shape by a method such as electroplating or printing. In this case, the substrate PS may be an insulating substrate, or may be a non-insulating substrate having an insulating layer formed at least at a position where the substrate extension pattern SEP is to be formed. The insulating layer may be used to electrically insulate the substrate extension pattern SEP from the substrate PS. In one or more examples, the insulating layer may be, for example, a silicon oxide layer, but is not limited thereto.

In one or more embodiments, the substrate extension pattern SEP may include the first magnetic material and the first resin as described above. For example, a premix including a preliminary resin material (e.g., an uncured epoxy resin material) and a magnetic particle material (e.g., a particle material of the first magnetic material) may be prepared, the premix may be molded into a substrate extension pattern SEP in a predetermined size and shape, and the molded substrate extension pattern SEP may then be attached to the substrate PS. In one or more examples, the substrate extension pattern SEP may be attached to the substrate PS by using, for example, an adhesive film. However, the embodiments are not limited to these configurations. In this case, the substrate PS may be any one of the insulating substrate and the non-insulating substrate.

Thereafter, referring to FIG. 3H together with FIGS. 3F and 3G, the semiconductor chip 120 obtained in FIG. 3F may be disposed on the substrate PS obtained in FIG. 3G. Specifically, a plurality of semiconductor chips 120 may be placed on the substrate connector region SCR of the substrate PS in a flip-chip form. As described above, the disposing position of the substrate extension pattern SEP of the substrate PS may correspond to the substrate connector region SCR of the substrate PS for mounting the semiconductor chip 120, and the size and shape of the substrate extension pattern SEP may correspond to the size and shape of the chip extension part 124 of the semiconductor chip 120. Accordingly, after the semiconductor chip 120 is placed on the substrate PS, the chip extension part 124 of the semiconductor chip 120 may overlap the substrate extension pattern SEP of the substrate PS in a direction in which the semiconductor chip 120 and the substrate PS are stacked. The chip extension part 124 and the substrate extension pattern SEP overlapping each other may generate a magnetic force therebetween, and at the same time, the generated magnetic force may be used to correct the warpage of the chip body 121 of the semiconductor chip 120, so as to reduce the difference in warpage between the chip body 121 and the substrate body 111, and to ensure effective wetting of the chip connection terminals 123 to the substrate connectors of the substrate PS. Thus, a non-wet defect in which the chip connection terminals 123 may not effectively wet the substrate connectors may be reduced or prevented.

Furthermore, as illustrated in FIG. 3H, in one or more examples, a plurality of semiconductor chips 120 may be placed on the substrate PS in the same manner as the manner described above. The warpage of the chip body 121 of each of the semiconductor chips 120 may be corrected in the same manner as the manner described above, and thus, the chip connection terminals 123 of each of the semiconductor chips 120 may effectively wet the corresponding substrate connectors of the substrate PS.

Subsequently, reflow soldering may be performed, such that the chip connection terminals 123 of the plurality of semiconductor chips 120 are each connected to the substrate connectors of the substrate PS. As such, the substrate PS mounted with the plurality of semiconductor chips 120 in the flip-chip form may be obtained.

Thereafter, referring to FIG. 3I, in one or more examples, a preliminary mold layer ML may be formed on the substrate PS. In one or more embodiments, the preliminary mold layer ML may be formed on the entire substrate PS by using a molding compound or an under-fill. For convenience of explanation, a top surface of each of the semiconductor chips 120 is illustrated in FIG. 3I. However, the embodiments are not limited by this illustration. The preliminary mold layer ML may cover the top surface of each of the semiconductor chips 120. In one or more examples, similar to the mold layer 130 described with reference to FIGS. 1A through 1C, the preliminary mold layer ML may fill (e.g., completely fill) spaces between the respective semiconductor chips 120, and the substrate PS and the substrate extension patterns SEP.

Furthermore, after the preliminary mold layer ML is formed, the obtained structure may be turned over, and substrate connection terminals may be formed on a surface of the substrate PS opposite to the surface on which the semiconductor chip 120 is mounted. In one or more examples, the substrate connection terminals of the substrate PS and an arrangement thereof are similar to the substrate connection terminals 112 and the arrangement thereof described with reference to FIGS. 1A through 1C and FIG. 2D, and thus, redundant descriptions thereof may be omitted. The substrate connection terminals of the substrate PS may be distributed in groups on the substrate PS, the respective groups of substrate connection terminals may be spaced apart from each other by a certain distance, and each of the groups of substrate connection terminals may be electrically connected to a corresponding one of the semiconductor chips 120 through an internal conductive path of the substrate PS.

Thereafter, referring to FIG. 3J, in one or more examples, the obtained structure of FIG. 3I may be cut. For example, the obtained structure of FIG. 3I may be cut along virtual lines illustrated in FIG. 3I by using a process, such as sawing, laser cutting, or any other suitable cutting process known to one of ordinary skill in the art, to separate each of the substrate PS and the preliminary mold layer ML into a plurality of portions, thereby forming a plurality of substrate bodies 111 and a plurality of mold layers 130, and individualizing the plurality of semiconductor chips 120 again. As such, a plurality of semiconductor packages 100 described with reference to FIGS. 1A through 1C may be obtained from the obtained structure of FIG. 3I.

According to the manufacturing method as described above, it may be possible to manufacture semiconductor packages according to example embodiments in batch. Therefore, process time may be saved, and a production yield may be increased.

FIGS. 4A through 4E are schematic diagrams illustrating intermediate steps of a method of manufacturing a semiconductor chip according to some embodiments. Hereinafter, for the sake of brevity, reference numerals that are the same as or similar to the reference numerals in FIGS. 3A through 3J may be used to denote the same or similar components, and redundant descriptions thereof may be omitted.

Referring to FIG. 4A, in one or more examples, a wafer W′ may be prepared. The wafer W′ prepared herein may be substantially the same as the wafer W prepared in FIG. 3A. For example, the wafer W′ may include a plurality of chips C′.

Unlike the performing of the slicing process on the wafer W described with reference to FIG. 3A, a scribing process may be performed herein on the wafer W′. For example, a plurality of scribing lanes SL may be formed on a side of the wafer W′ exposing active surfaces of chips C′. As illustrated in FIG. 4A, the plurality of scribing lanes SL may extend between the plurality of chips C′, such that the plurality of chips C′ are separated from and individual of each other in circuit configuration. Each of the plurality of scribing lanes SL may extend into the wafer W′, but may not penetrate the wafer W′. That is, the plurality of scribing lanes SL may be trenches formed in the wafer W′, while the plurality of chips C′ separated from each other by the plurality of scribing lanes SL may still be connected to each other through portions of the wafer W′ under bottom surfaces of the scribing lanes SL. In this case, the performing of subsequent processes may be benefited. In one or more examples, the scribing process described herein may be any suitable process for scribing a wafer without being particularly limited, as long as the process is forms the plurality of scribing lanes SL described herein that separate the plurality of chips C′ from each other in circuit configuration, rather than singularizing them thoroughly.

Thereafter, referring to FIG. 4B, in one or more examples, protection patterns PR′ may be formed on the plurality of chips C′ of the wafer W′, respectively. The protection patterns PR′ may be used to protect, for example, the active surface of the chip C′ and pads and connection terminals thereon, etc. The material and process used to form the protection patterns PR′ may be substantially the same as those of the protection patterns PR described with reference to FIG. 3C, and thus, redundant descriptions thereof may be omitted.

Thereafter, referring to FIG. 4C, in one or more examples, a chip extension layer CEL′ may be formed on the obtained structure of FIG. 4B. For example, as illustrated in FIG. 4C, the chip extension layer CEL′ may be formed on the entire wafer W′, fill the plurality of scribing lanes SL (see FIG. 4B), and cover and contact a side surface of each of the chips C′. Except that the chip extension layer CEL′ is formed directly on the wafer W′, other descriptions of the chip extension layer CEL′ may be substantially the same as or similar to the above descriptions of the chip extension layer CEL, and thus, redundant descriptions thereof may be omitted.

Thereafter, referring to FIG. 4D, the protection patterns PR′ may be removed from the obtained structure of FIG. 4C to expose the active surfaces of the chips C′ again. A method of removing the protection patterns PR′ may be substantially the same as or similar to the method of removing the protection patterns PR described with reference to FIG. 3E, and thus, redundant descriptions thereof may be omitted.

Thereafter, referring to FIG. 4E, a slicing process may be performed on the obtained structure of FIG. 4D to singularize the plurality of chips C′. The slicing process described herein may be substantially the same as or similar to the slicing process described with reference to FIG. 3A, and thus, redundant descriptions thereof may be omitted. As illustrated in FIG. 4E, after the slicing process is completed, a plurality of semiconductor chips 120 with reference to FIGS. 1A through 1C may be obtained from the obtained structure of FIG. 4D, each of which includes a chip body 121 (e.g., the chip C′), chip pads 122 and chip connection terminals 123 formed on an active surface of the chip body 121, and a chip extension part 124 formed on a side surface of the chip body 121.

In the manufacturing method of the semiconductor chip described with reference to FIGS. 4A through 4E, it may be allowed to form the chip extension layer CEL′ directly on the wafer W′ by performing the scribing process on the wafer W′. That is, the chip extension layer CEL′ may be formed in situ on the wafer W′. As such, compared to the manufacturing method of the semiconductor chip described with reference to FIGS. 3A through 3F, process steps for manufacturing a semiconductor chip according to example embodiments may be further reduced, and thus process time may be further saved and a production yield may further be increased. In or more examples, since the operation for transferring the chip bodies, which are dies, is not required, damage or warpage of the dies that may be caused during the transferring operation may be further reduced. Therefore, the reliability of the semiconductor package may be improved.

Additionally, processes of mounting the plurality of semiconductor chips 120 obtained according to FIGS. 4A through 4E on a substrate to manufacture semiconductor packages may be substantially the same as or similar to the processes described with reference to FIGS. 3G through 3J. Accordingly, based on the semiconductor chips 120 of FIGS. 4A through 4E, it may also be possible to manufacture the semiconductor packages 100 with reference to FIGS. 1A through 1C in batch.

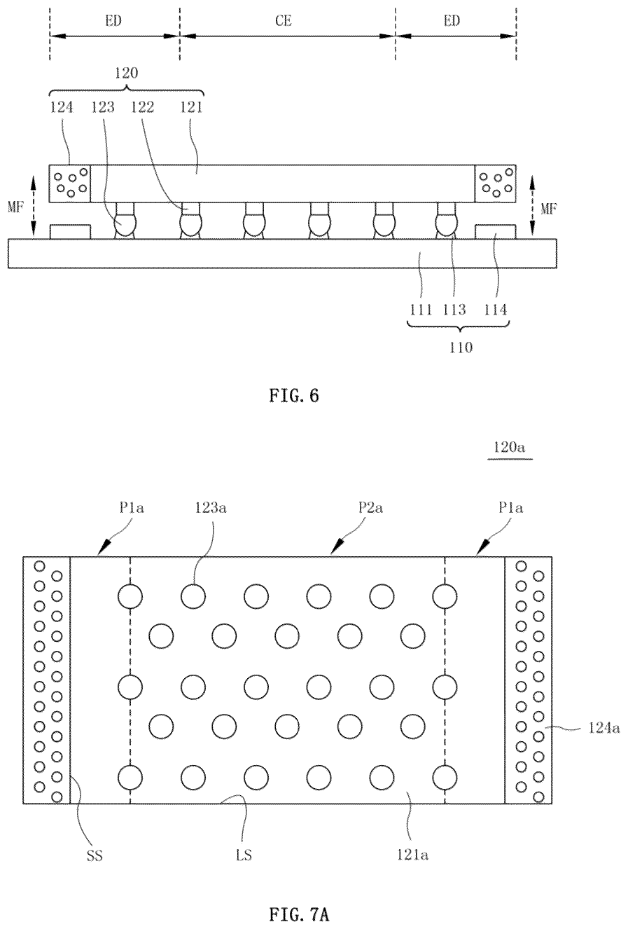

Hereinabove, the semiconductor packages according to the embodiments and the manufacturing methods thereof have been described in detail with reference to FIGS. 1A through 4E. Hereinafter, the warpage correction implemented in the semiconductor package according to the embodiments will be described in detail in conjunction with FIGS. 5 and 6.

FIG. 5 is a schematic cross-sectional view illustrating a step of mounting a semiconductor chip to a substrate. Specifically, FIG. 5 illustrates a case of mounting a semiconductor chip to a substrate by a flip-chip process in the prior art.

FIG. 6 is a schematic cross-sectional view illustrating a step of mounting a semiconductor chip to a substrate according to one or more embodiments of the present disclosure. Specifically, FIG. 6 illustrates the case described with reference to FIG. 2C, and may be applied to the case described with reference to FIG. 3H. However, it should be understood that the descriptions given below in conjunction with FIG. 6 are not limited to only FIGS. 2C and 3H.

As illustrated in FIG. 5, when a semiconductor chip 12 is placed on a substrate 13 in a flip-chip form, an interval between the semiconductor chip 12 and the substrate 13 may be uneven due to the warpage of the semiconductor chip 12. This results in a portion of chip connection terminals 12a of the semiconductor chip 12 not effectively contacting and wetting substrate connectors 13a of the substrate 13. In this case, even after undergoing reflow soldering, the portion of the chip connection terminals 12a of the semiconductor chip 12 may not be connected to the corresponding substrate connectors 13a, and therefore, an electrical connection defect, such as disconnection or virtual soldering, between the chip connection terminals 12a of the semiconductor chip 12 and the substrate connectors 13a of the substrate 13 may occur. In one or more examples, when the semiconductor chip 12 is a die, on the one hand, since sizes of respective components included in the semiconductor chip 12 is limited, the warpage of the semiconductor chip 12 may not be corrected by utilizing a modification to the original components of the semiconductor chip 12 in the case of ensuring the original components of the semiconductor chip 12 to implement the same or approximate performances as well. In one or more examples, since the semiconductor chip 12 may be vulnerable because of being unencapsulated, damage to the semiconductor chip 12 (e.g., cracks of a chip body, breakages of internal circuits, etc.) may be caused by a force for warpage correction when the force is applied to the semiconductor chip 12 within a relatively large region.

According to the embodiments of the present disclosure, as illustrated in FIG. 6, a semiconductor chip 120 may include a chip extension part 124 formed on a side surface of the chip body 121, a substrate 110 may include a substrate extension part 114 formed on a surface of a substrate body 111 facing the semiconductor chip 120, and the chip extension part 124 and the substrate extension part 114 may overlap each other in a direction in which the semiconductor chip 120 and the substrate 110 are stacked. As described above with reference to FIGS. 1A through 1C, both the chip extension part 124 and the substrate extension part 114 may have first and second magnetisms, respectively. The chip extension part 124 and the substrate extension part 114 overlapping each other may generate a magnetic force MF therebetween. The magnetic force MF generated by the chip extension part 124 and the substrate extension part 114 may be used to correct the warped chip body 121 to restore the chip body 121 to be flat with respect to the substrate body 111. Thus, effective contact and wetting between all of chip connection terminals 123 of the semiconductor chip 120 and corresponding substrate connectors 113 of the substrate 110 may be ensured. Therefore, an electrical connection defect, such as disconnection or virtual soldering, between the chip connection terminals 123 and the substrate connectors 113 may be reduced or prevented.

In one or more embodiments, when the chip body 121 of FIG. 6 has a concave-surface form with edges ED protruding upwardly (e.g., away from the substrate) and a center CE recessed downwardly (e.g., toward the substrate) similar to that illustrated in FIG. 5, the chip extension part 124 and the substrate extension part 114 of FIG. 6 may be configured to generate a magnetic attraction force between each other. However, the embodiments are not limited thereto. For example, in contrast to the warpage form illustrated in FIG. 5, the chip body 121 of FIG. 6 may have a convex-surface form with edges ED recessed downwardly and a center CE protruding upwardly. In this case, the chip extension part 124 and the substrate extension part 114 of FIG. 6 may be configured to generate a magnetic repulsion force between each other.

A magnitude of the generated magnetic force (e.g., the magnetic attraction force or the magnetic repulsion force) may vary depending on a degree of warpage of the chip body 121. For example, as the degree of warpage of the chip body 121 increases, the chip extension part 124 and the substrate extension part 114 may be configured to generate an increased magnetic force. In one or more embodiments, by changing the type of the magnetic material included in the chip extension part 124 and/or the type of the magnetic material included in the substrate extension part 114, it may be controlled whether the magnetic attraction force or the magnetic repulsion force is generated between the chip extension part 124 and the substrate extension part 114. That is, the exhibited magnetism of the chip extension part 124 by including the magnetic material may be inversing to or the same as the exhibited magnetism of the substrate extension part 114 by including the magnetic material. Also, in one or more embodiments, by adjusting the type and/or concentration of the magnetic material included in the chip extension part 124, the type and/or concentration of the magnetic material included in the substrate extension part 114, the size (e.g., volume) of the chip extension part 124, the size (e.g., volume) of the substrate extension part 114, and/or the overlapping degree and/or the interval between the chip extension part 124 and the substrate extension part 114, the magnitude of the magnetic force MF generated between the chip extension part 124 and the substrate extension part 114 may be adjusted.

According to example embodiments, since the warpage of the chip body 121 may be corrected by additionally forming the chip extension part 124 and the substrate extension part 114, a force sufficient to correct the warpage of the chip body 121 may be provided without affecting the performances of the original components (e.g., the chip body, the chip pad, the chip connection terminal, etc.) of the semiconductor chip 120, and thus, this may be applicable to a die of which the size is limited. Also, as described above, the chip extension part 124 described herein may be formed by a molding method that is advantageous to the die (e.g., has no or little damage to the die under the condition of a forming process thereof), and thus, the properties and characteristics of the chip body 121 as a die may substantially not be affected. Furthermore, because the chip extension part 124 and the substrate extension part 114 are additionally formed, the logic of structural and electrical designs for the semiconductor chip, the substrate, and the semiconductor package may remain substantially unchanged, and thus, the embodiments of the present disclosure may be advantageously applicable to warpage corrections of various types of die-level chips.

In one or more examples, since the chip extension part 124 and the substrate extension part 114 are additional components with respect to the chip body 121 and the substrate body 111, respectively, the positions, sizes, and/or shapes of the chip extension part 124 and the substrate extension part 114 may be designed relatively freely or flexibly. Compared to correcting a warpage of a chip by applying a force to the chip within a relatively large region, the correction of warpage for the chip body 121 having a complex form of warpage may be implemented in the case of avoiding damage to the chip body 121 as a die.

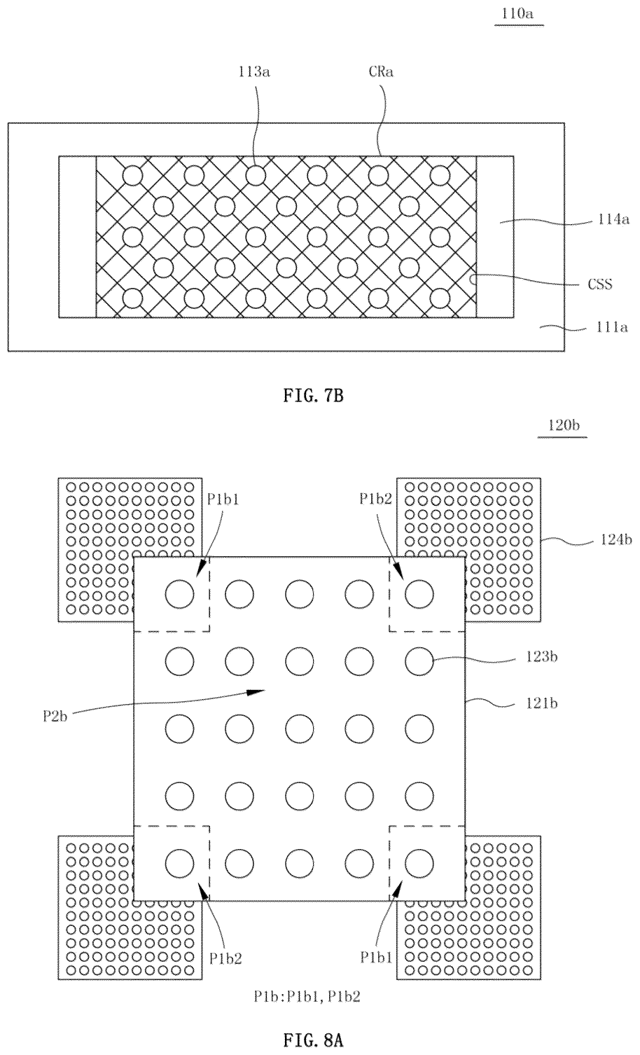

FIGS. 7A and 7B schematically illustrate a bottom view of a semiconductor chip and a top view of a substrate according to some embodiments. Specifically, FIG. 7A illustrates a bottom view of a semiconductor chip 120a, and FIG. 7B illustrates a top view of a substrate 110a.

Referring to FIGS. 7A and 7B, in one or more examples, a chip body 121a of a semiconductor chip 120a according to the embodiments may have a long rectangular shape in a plan view. Due to the stress distribution characteristics of the chip body 121a itself, the chip body 121a having the rectangular plane shape may generally exhibit a warping behavior at short edges SS thereof. Specifically, the chip body 121a may include two first portions Pla adjacent to the short sides SS thereof and a second portion P2a between the two first portions Pla, along a direction in which long sides LS thereof extend, and the two first portions Pla of the chip body 121a may exhibit the warping behavior. For example, when viewed in a cross-sectional view of the chip body 121a taken along the direction in which the long sides LS thereof extend, the two first portions Pla of the chip body 121a may be upwardly warped or downwardly curved with respect to the second portion P2a of the chip body 121a. That is, a top surface or a bottom surface of the chip body 121a in this cross-sectional view may be in a shape of concave curve with a lower center and two higher ends, or a shape of convex curve with a higher center and two lower ends. When the chip body 121a has a warpage in which the top surface or the bottom surface is in the shape of concave curve, a problem that a chip connection terminal 123a may not effectively wet a substrate connector 113a of a substrate 110a may occur at the first portions Pla of the chip body 121a. In one or more examples, when the chip body 121a has a warpage in which the top surface or the bottom surface is in the shape of concave curve, a problem that the chip connection terminal 123a may not effectively wet the substrate connector 113a of the substrate 110a may occur at the second portion P2a of the chip body 121a.

Since the chip body 121a described herein exhibits the warping behavior at the two first portions Pla at the short edges SS thereof, chip extension parts 124a may be disposed on side surfaces of the chip body 121a at the short edges SS thereof. In this case, the chip extension parts 124a may not be disposed on side surfaces of the chip body 121a at the long sides LS thereof. That is, the chip extension parts 124a may be disposed on a portion of the side surface of the chip body 121a corresponding to the two first portions Pla. As illustrated in FIG. 7A, the chip extension parts 124a may be disposed on the side surface of the chip body 121a along both the short sides SS of the chip body 121a. However, the embodiments are not limited thereto. For example, according to the degree of warpage of the first portion P1a of the chip body 121a, the chip extension part 124a may be disposed on only a portion of the side surface of the chip body 121a at the short side SS thereof. For another example, according to whether the degrees of warpage of the two first portions P1a of the chip body 121a are the same or different, two chip extension parts 124a disposed at two short edges SS of the chip body 121a may have the same or different lengths in a direction in which the short edges SS of the chip body 121a extend, or have the same or different thicknesses in a direction in which the side surfaces of the chip body 121a extend. Furthermore, the semiconductor chip 120a described herein may be formed by, for example, the manufacturing method of the semiconductor chip 120 described with reference to FIGS. 2A and 2B. In the semiconductor chip 120a obtained thereby, the overlapping relationship between the chip extension part 124a and the side surface of the chip body 121a in a direction parallel to the top surface or the bottom surface of the chip body 121a (or perpendicular to a thickness direction of the chip body 121a) may be substantially the same as or similar to that between the chip extension part 124 and the side surface 121S of the chip body 121 in the first direction D1 and/or the second direction D2 described with reference to FIGS. 1A and 1C, and thus, redundant descriptions thereof may be omitted.

In one or more examples, a substrate body 111a of the substrate 110a may have a connector region CRa in which the substrate connector 113a for the connection to the chip connection terminal 123a of the semiconductor chip 120a is disposed. The connector region CRa may have a rectangular shape corresponding to the shape of the chip body 121a in a plan view. As disclosed previously, substrate extension parts 114a of the substrate 110a may have a correspondingly overlapping relationship with the chip extension parts 124a of the semiconductor chip 120a. Accordingly, as illustrated in FIG. 7B, two substrate extension parts 114a adjacent to short sides CSS of the connector region CRa may be disposed on the substrate body 111a. Similar to those disclosed above, the positions of the substrate extension parts 114a on the substrate body 111a may be appropriately disposed, as long as when the semiconductor chip 120a is placed on the substrate 110a, the chip extension parts 124a and the substrate extension parts 114a may overlap each other in a direction in which the chip body 121a and the substrate body 111a are stacked and generate a magnetic force sufficient to correct the warpage of the chip body 121a. In some embodiments, when the semiconductor chip 120a is placed on the substrate 110a, the chip extension parts 124a and the substrate extension parts 114a may completely overlap each other in the direction in which the chip body 121a and the substrate body 111a are stacked. Furthermore, the substrate 110a may be manufactured by, for example, the manufacturing method of the substrate 110 described with reference to FIG. 2C. In the substrate 110a obtained thereby, the arrangement relationship between the substrate extension parts 114a and the substrate body 111a may be substantially the same as or similar to that between the substrate extension part 114 and the substrate body 111 described with reference to FIGS. 1A and 1B, and thus, redundant descriptions thereof may be omitted.

In the embodiments described with reference to FIGS. 7A and 7B, when the semiconductor chip 120a is mounted on the substrate 110a in a flip-chip form, the chip extension parts 124a and the substrate extension parts 114a may overlap each other in the direction in which the chip body 121a and the substrate 110a are stacked, and may generate a magnetic force (e.g., a magnetic attraction force or a magnetic repulsion force) therebetween. The generated magnetic force may be used to correct the warpage of the two first portions P1a of the chip body 121a at the short edges SS thereof, such that the chip body 121a may be restored to be flat with respect to the substrate body 111a. Thus, a non-wet defect of the chip connection terminal 123a to the substrate connector 113a of the substrate 110a due to the warping behavior of the chip body 121a may be reduced or prevented. As a result, the reliability of the electrical connection between the semiconductor chip 120a and the substrate 110a may be improved.

In the embodiments disclosed with reference to FIGS. 7A and 7B, the chip extension parts 124a may be disposed for only the first portions P1a of the chip body 121a at the short sides SS that exhibit the warping behavior. As such, forces may be applied more precisely to portions of the chip body 121a on which the warpage correction is required to be performed. Accordingly, unnecessary forces may be avoided to be applied to other portions of the chip body 121a while the effective warpage correction is ensured. As a result, the warpage correction for the die-level chip body 121a may be benefited.

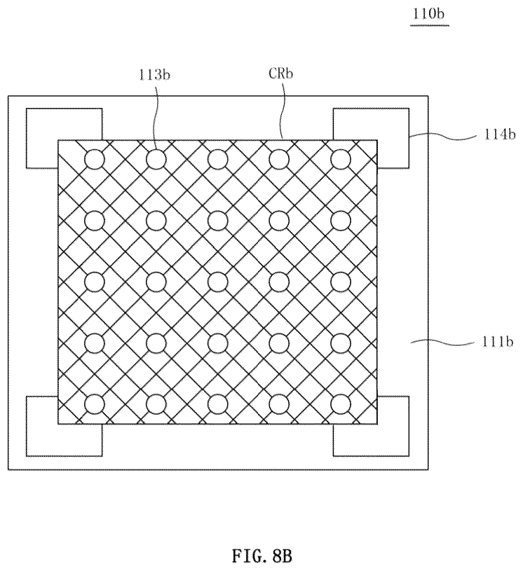

FIGS. 8A and 8B schematically illustrate a bottom view of a semiconductor chip and a top view of a substrate according to some embodiments. Specifically, FIG. 8A illustrates a bottom view of a semiconductor chip 120b, and FIG. 8B illustrates a top view of a substrate 110b.

Compared to the embodiments described with reference to FIGS. 7A and 7B, as illustrated in FIG. 8A, a chip body 121b of a semiconductor chip 120b may have a square shape in a plan view, and as illustrated in FIG. 8B, a substrate body 111b of a substrate 110b may also have a connector region CRb in a square shape.

Due to the stress distribution characteristics of the chip body 121b itself, the chip body 121b having the square plane shape may generally exhibit a warping behavior at four corners. In some cases, the four corners of the chip body 121b may each be upwardly warped or downwardly curved with respect to a center of the chip body 121b. In other cases, the chip body 121b may have a more complex form of warpage, for example, a saddle-shaped form of warpage in a three-dimensional space. The present embodiment will be described, taking a case where the chip body 121b has the saddle-shaped warpage as an example.

Specifically, the chip body 121b may include four corner portions (i.e., first portions P1b) at the four corners thereof and a center portion (e.g., a second portion P2b) among the four corner portions. Each of two first portions P1b1 of the chip body 121b at two corners on one diagonal may be upwardly warped or downwardly curved with respect to the second portion P2b of the chip body 121b, while each of two first portions P1b2 of the chip body 121b at two corners on the other diagonal may be downwardly curved or upwardly curved with respect to the second portion P2b of the chip body 121b, and thus, the warped chip body 121b may have the saddle shape in whole.

In this case, since the warping behavior of the chip body 121b occurs at the four corners thereof, four chip extension parts 124b may be disposed on side surfaces of the chip body 121b at the four corners of the chip body 121b, respectively, as illustrated in FIG. 8A. That is, the chip extension parts 124b may be disposed on portions of the side surface of the chip body 121b corresponding to the four first portions P1b. For example, each of the chip extension part 124b may be in a shape of “L”, and contact two side surfaces of the chip body 121b meeting with a corresponding one of the corners of the chip body 121b at the corresponding corner. For example, each of the chip extension parts 124b may surround a corresponding one of the corners of the chip body 121b. A forming method of the chip extension parts 124b and a contacting form between the chip extension parts 124b and the side surface of the chip body 121b may be substantially the same as or similar to the forming method and the contacting form of the chip extension part 124 or the chip extension parts 124a as described above, and thus redundant descriptions thereof may be omitted.

Referring to FIG. 8B, in one or more examples, four substrate extension parts 114b may be disposed at the four corners of the connector region CRb, respectively. Each of the substrate extension parts 114b may have substantially the same shape as a corresponding one of the chip extension parts 124b. For example, each of the substrate extension parts 114b may also have a shape of “L”, and surround a corresponding one of the corners of the connector region CRb. A forming method of the substrate extension parts 114b and an arrangement relationship between the substrate extension parts 114b and the substrate body 111b may be substantially the same as or similar to the forming method and the arrangement relationship of the substrate extension parts 114b described above, and thus redundant descriptions thereof may be omitted.

Referring to FIGS. 8A and 8B together, when the semiconductor chip 120b is placed on the substrate 110b in a flip-chip form, the chip extension parts 124b and the substrate extension parts 114b may overlap (e.g., completely overlap) each other, and may generate a magnetic force (e.g., a magnetic attraction force or a magnetic repulsion force) therebetween. As described above, the chip body 121b may have two first portions P1b1 on one diagonal and upwardly warped (i.e., becoming away from the substrate body 111b) with respect to the second portion P2b, and two first portions P1b2 on the other diagonal and downwardly curved (i.e., becoming proximate to the substrate body 111b) with respect to the second portion P2b. Accordingly, the chip extension parts 124b disposed adjacent to the first portions P1b1 of the chip body 121b on the one diagonal and the substrate extension parts 114b corresponding thereto may be configured to generate a magnetic attraction force therebetween, so as to correct the upward warpage of the first portions P1b1 of the chip body 121b on the one diagonal. The chip extension parts 124b disposed adjacent to the first portions P1b2 of the chip body 121b on the other diagonal and the substrate extension part 114b corresponding thereto may be configured to generate a magnetic repulsion force therebetween, so as to correct the downward curve of the first portions P1b2 of the chip body 121b on the other diagonal. As such, the warpage of the chip body 121b having the saddle shape may be effectively corrected.

In addition, in the embodiments described with reference to FIGS. 8A and 8B, a plurality of groups of chip extension parts 124b and substrate extension parts 114b respectively generating the magnetic attraction force or the magnetic repulsion force may be disposed for the chip body 121b having various complex forms of warpage. As such, appropriate forces may be applied more precisely to portions of the chip body 121b on which the warpage correction is required to be performed. Thus, unnecessary forces may be avoided to be applied to other portions of the chip body 121b while the effective warpage correction is ensured. As a result, the complex warpage correction for the die-level chip body 121b may be benefited.

The semiconductor packages and the configurations of the chip extension parts and the substrate extension parts included therein according to the embodiments are described above with reference to FIGS. 1A through 1C and FIGS. 7A through 8B, but the example embodiments of the present disclosure may be variously modified without departing from the inventive concept disclosed above. In general, according to the present disclosure, the chip extension part may be disposed on the side surface of the portion, which exhibits the warping behavior, of the chip body in correspondence with the form of warpage of the chip body, while the substrate extension part may be disposed on the substrate body in correspondence with the chip extension part, such that when the semiconductor chip including the chip body and the chip extension part is placed in the flip-chip form on the substrate including the substrate body and the substrate extension part, the chip extension part and the substrate extension part may overlap each other in the direction in which the semiconductor chip and the substrate are stacked, so as to generate therebetween the magnetic force sufficient to correct the warpage of the chip body (e.g., to restore the warped chip body to be flat). As such, the respective chip connection terminals of the semiconductor chip are each configured to contact and wet the substrate connectors of the substrate, and thus the non-wet defect occurring between the chip connection terminals and the substrate connectors may be reduced or prevented. As a result, the reliability of the electrical connection between the semiconductor chip and the substrate may be improved.

In addition, as described above, the chip extension part and the substrate extension part according to the example embodiments of the present disclosure may be disposed relatively freely in the positions, sizes, and/or shapes thereof according to the requirements of the warpage correction, and may be configured to generate the magnetic force having the appropriate form (e.g., the attraction force or the repulsion force) and the appropriate magnitude according to the form of warpage. Thus, the force applied to the die-level semiconductor chip (e.g., the chip bodies 121, 121a, and 121b discussed above) by the chip extension part and the substrate extension part described herein may be precisely controllable. As a result, the warpage correction (especially, the complex warpage correction) for the die may be effectively implemented without damaging the structure, properties, and performance of the die.

Although the aspects of the example embodiments have been specifically illustrated and described, it will be understood that various changes in forms and details may be made therein without departing from the spirit and scope of the appended claims.

What is claimed is:

1. A semiconductor package comprising:
a substrate comprising a substrate body, a substrate extension part, and a substrate connection terminal, the substrate body having a first surface and a second surface opposite to the first surface, the substrate extension part being on the first surface of the substrate body, the substrate connection terminal being on the second surface of the substrate body, and the substrate extension part having a first magnetism;
a semiconductor chip on the first surface of the substrate body, the semiconductor chip comprising a chip body and a chip extension part, the chip extension part being on a side surface of the chip body, the chip extension part having a second magnetism; and
a mold layer encapsulating the semiconductor chip on the first surface of the substrate body,
wherein the substrate extension part and the chip extension part overlap in a first direction, and the substrate extension part and the chip extension part are spaced apart in the first direction.

2. The semiconductor package of claim 1, wherein the chip extension part is in contact with the side surface of the chip body.

3. The semiconductor package of claim 1, wherein the chip extension part has a top surface substantially coplanar with a first surface of the chip body, the first surface of the chip body facing away from the substrate body.

4. The semiconductor package of claim 1,
wherein the chip body comprises a plurality of first portions and a second portion between the plurality of first portions, and
wherein the chip extension part is on at least one portion of the side surface of the chip body corresponding to the plurality of first portions.

5. The semiconductor package of claim 1, wherein the chip extension part covers the entire side surface of the chip body.

6. The semiconductor package of claim 1, wherein the substrate extension part completely overlaps the chip extension part in the first direction.

7. The semiconductor package of claim 1, wherein
the substrate further comprises a substrate connector at a portion of the first surface of the substrate body facing the chip body,
the chip body has a first surface and a second surface opposite to the first surface, the second surface of the chip body facing the substrate body,
the semiconductor chip further comprises a chip pad at the second surface of the chip body and a chip connection terminal coupled to the chip pad, and
the chip connection terminal is coupled to the substrate connector.

8. The semiconductor package of claim 1,
wherein the substrate extension part comprises a first magnetic material, and
wherein the chip extension part comprises a second magnetic material and a second resin.

9. The semiconductor package of claim 1, wherein the chip body is a die.

10. The semiconductor package of claim 1, wherein the substrate extension part and the chip extension part are configured to:
generate a magnetic force between each other based on the semiconductor chip being placed on the substrate body,
wherein the magnetic force is configured correct a warpage of the chip body.

11. A semiconductor device comprising:
a semiconductor package comprising:
a substrate comprising a substrate body, a substrate extension part, and a substrate connection terminal, the substrate body having a first surface and a second surface opposite to the first surface, the substrate extension part being on the first surface of the substrate body, the substrate connection terminal being on the second surface of the substrate body, and the substrate extension part having a first magnetism;
a semiconductor chip on the first surface of the substrate body, the semiconductor chip comprising a chip body and a chip extension part, the chip extension part being on a side surface of the chip body, the chip extension part having a second magnetism; and
a mold layer encapsulating the semiconductor chip on the first surface of the substrate body,
wherein the substrate extension part and the chip extension part overlap in a first direction, and the substrate extension part and the chip extension part are spaced apart in the first direction.

12. The semiconductor device of claim 11, wherein the chip extension part is in contact with the side surface of the chip body.

13. The semiconductor device of claim 11, wherein the chip extension part has a top surface substantially coplanar with a first surface of the chip body, the first surface of the chip body facing away from the substrate body.

14. The semiconductor device of claim 11,
wherein the chip body comprises a plurality of first portions and a second portion between the plurality of first portions, and
wherein the chip extension part is on at least one portion of the side surface of the chip body corresponding to the plurality of first portions.

15. The semiconductor device of claim 11, wherein the chip extension part covers the entire side surface of the chip body.

16. The semiconductor device of claim 11, wherein the substrate extension part completely overlaps the chip extension part in the first direction.

17. The semiconductor device of claim 11, wherein
the substrate further comprises a substrate connector at a portion of the first surface of the substrate body facing the chip body,
the chip body has a first surface and a second surface opposite to the first surface, the second surface of the chip body facing the substrate body,
the semiconductor chip further comprises a chip pad at the second surface of the chip body and a chip connection terminal coupled to the chip pad, and
the chip connection terminal is coupled to the substrate connector.

18. The semiconductor device of claim 11, wherein the substrate extension part comprises a first magnetic material, and
wherein the chip extension part comprises a second magnetic material and a second resin.

19. The semiconductor device of claim 11, wherein the chip body is a die.

20. The semiconductor device of claim 11, wherein the substrate extension part and the chip extension part are configured to:
generate a magnetic force between each other based on the semiconductor chip being placed on the substrate body,
wherein the magnetic force is configured correct a warpage of the chip body.
